(19) United States
(12) Patent Application Publication
(10) Pub. No.: US 2025/0212540 A1
(43) Pub. Date: Jun. 26, 2025

(54) IMAGING DEVICE AND ELECTRONIC DEVICE

(71) Applicant: SONY SEMICONDUCTOR SOLUTIONS CORPORATION, KANAGAWA (JP)

(72) Inventor: JUNJI NARUSE, KANAGAWA (JP)

(21) Appl. No.: 18/848,066

(22) PCT Filed: Feb. 24, 2023
(86) PCT No.: PCT/JP2023/006702

§ 371 Date: Sep. 17, 2024

(30) Foreign Application Priority Data
Mar. 28, 2022 (JP) 2022-051555

(51) Int. Cl. H10F 39/00

(52) U.S. Cl. CPC H10F 39/8053; H10F 39/8023

(57) ABSTRACT

Provided is an imaging device (10) including a pixel array unit (33) formed by arraying unit regions including a plurality of imaging elements including a first imaging element (100a) and a second imaging element (100b) in a two-dimensional array, in which each of the first imaging element and the second imaging element includes a color filter (154) that transmits light having a wavelength of a predetermined wavelength band, and the color filter included in the first imaging element has a higher refractive index than a refractive index of the color filter included in the second imaging element.

### FIELD

The present disclosure relates to an imaging device and an electronic device.

### BACKGROUND

An imaging device is required to expand an illuminance range, that is, a dynamic range of a subject that can be imaged with gradation. Therefore, as disclosed in Patent Literature 1 below, a technology of expanding a dynamic range by intentionally providing a sensitivity difference between imaging elements by changing areas in plan view of the imaging elements that detect the same color light has been proposed.

### CITATION LIST

### Patent Literature

Patent Literature 1: JP 2017-163010 A

### SUMMARY

### Technical Problem

However, in the technology disclosed in Patent Literature 1 described above, the dynamic range can be expanded basically only by increasing an area ratio between an imaging elements 100 that detect the same color light, so that there is a limit in expansion of the dynamic range. In order to expand the dynamic range, it is considered to provide a waveguide and the like in the imaging element, but since the number of steps increases, it is difficult to avoid an increase in manufacturing cost of the imaging device.

Therefore, the present disclosure proposes an imaging device and an electronic device capable of expanding a dynamic range while suppressing an increase in manufacturing cost.

### Solution to Problem

According to the present disclosure, there is provided an imaging device including a pixel array unit. The pixel array unit is formed by arraying unit regions including a plurality of imaging elements including a first imaging element and a second imaging element in a two-dimensional array. In the imaging device, each of the first imaging element and the second imaging element includes a color filter that transmits light having a wavelength of a predetermined wavelength band, and the color filter included in the first imaging element has a higher refractive index than a refractive index of the color filter included in the second imaging element.

Furthermore, according to the present disclosure, there is provided an electronic device equipped with an imaging device. In the electronic device, the imaging device includes a pixel array unit, the pixel array unit is formed by arraying unit regions including a plurality of imaging elements including a first imaging element and a second imaging element in a two-dimensional array, each of the first imaging element and the second imaging element includes a color filter that transmits light having a wavelength of a predetermined wavelength band, and the color filter included in the first imaging element has a higher refractive index than a refractive index of the color filter included in the second imaging element.

### BRIEF DESCRIPTION OF DRAWINGS

FIG. 1 is an illustrative diagram illustrating a planar configuration example of an imaging device 10 according to an embodiment of the present disclosure.

FIG. 2 is an illustrative diagram illustrating a cross-sectional configuration example of an imaging element 100 according to a comparative example.

FIG. 3A is an illustrative diagram illustrating a planar configuration example of a color filter unit 74 according to a first embodiment of the present disclosure.

FIG. 3B is an illustrative diagram illustrating a cross-sectional configuration example of the color filter unit 74 according to the first embodiment of the present disclosure.

FIG. 4A is an illustrative diagram illustrating a planar configuration example of a color filter unit 74 according to a modification 1 of the first embodiment of the present disclosure.

FIG. 4B is an illustrative diagram illustrating a cross-sectional configuration example of the color filter unit 74 according to the modification 1 of the first embodiment of the present disclosure.

FIG. 5A is an illustrative diagram illustrating a planar configuration example of a color filter unit 74 according to a modification 2 of the first embodiment of the present disclosure.

FIG. 5B is an illustrative diagram illustrating a cross-sectional configuration example of the color filter unit 74 according to the modification 2 of the first embodiment of the present disclosure.

FIG. 6A is an illustrative diagram illustrating a planar configuration example of a color filter unit 74 according to a second embodiment of the present disclosure.

FIG. 6B is an illustrative diagram illustrating a cross-sectional configuration example of the color filter unit 74 according to the second embodiment of the present disclosure.

FIG. 7 is an illustrative diagram illustrating a cross-sectional configuration example of a color filter unit 74 according to a third embodiment of the present disclosure.

FIG. 8 is an illustrative diagram illustrating a cross-sectional configuration example of a color filter unit 74 according to a fourth embodiment of the present disclosure.

FIG. 9A is an illustrative diagram illustrating a planar configuration example of a color filter unit 74 according to a fifth embodiment of the present disclosure.

FIG. 9B is an illustrative diagram illustrating a cross-sectional configuration example of the color filter unit 74 according to the fifth embodiment of the present disclosure.

FIG. 10A is an illustrative diagram illustrating a planar configuration example of a color filter unit 74 according to a modification 1 of the fifth embodiment of the present disclosure.

FIG. 10B is an illustrative diagram illustrating a cross-sectional configuration example of the color filter unit 74 according to the modification 1 of the fifth embodiment of the present disclosure.

FIG. 11A is an illustrative diagram illustrating a planar configuration example of a color filter unit 74 according to a modification 2 of the fifth embodiment of the present disclosure.

FIG. 11B is an illustrative diagram illustrating a cross-sectional configuration example of the color filter unit 74 according to the modification 2 of the fifth embodiment of the present disclosure.

FIG. 12A is an illustrative diagram illustrating a planar configuration example of a color filter unit 74 according to a modification 3 of the fifth embodiment of the present

### DISCLOSURE

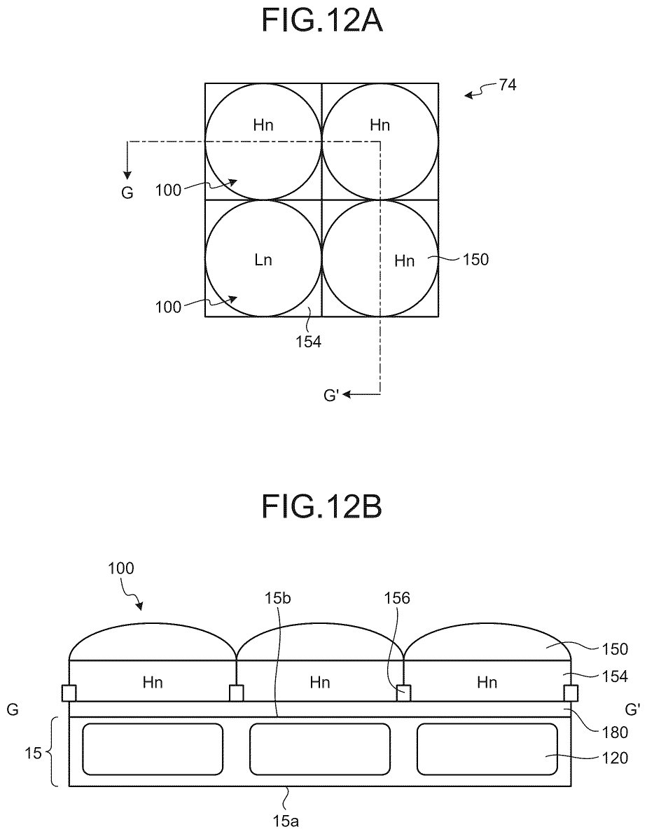

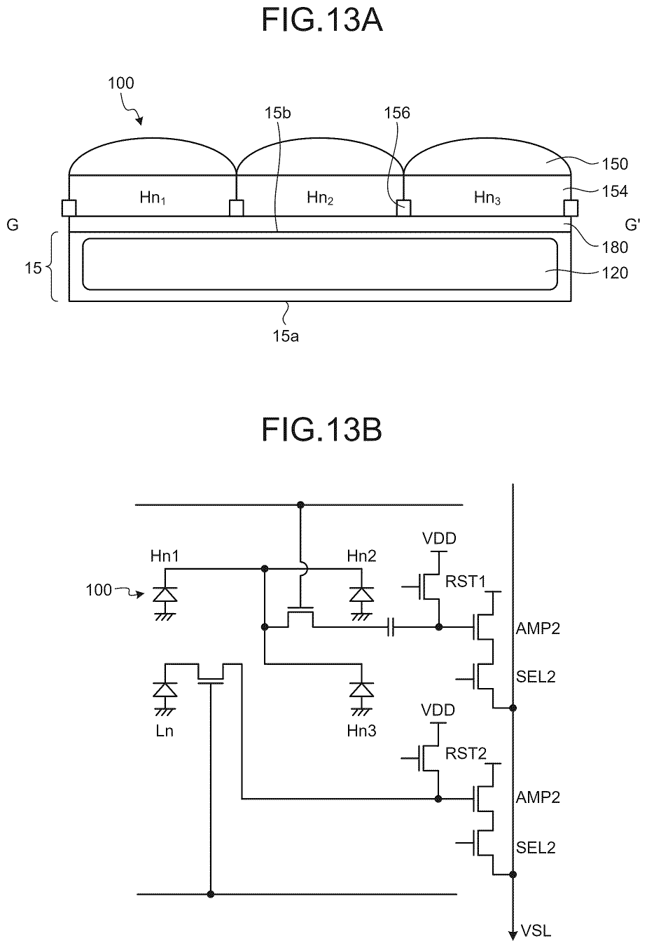

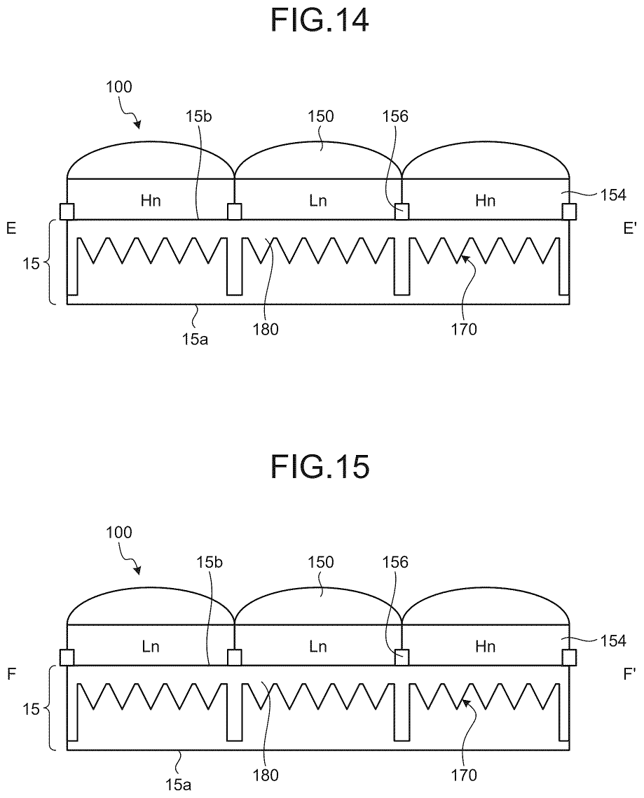

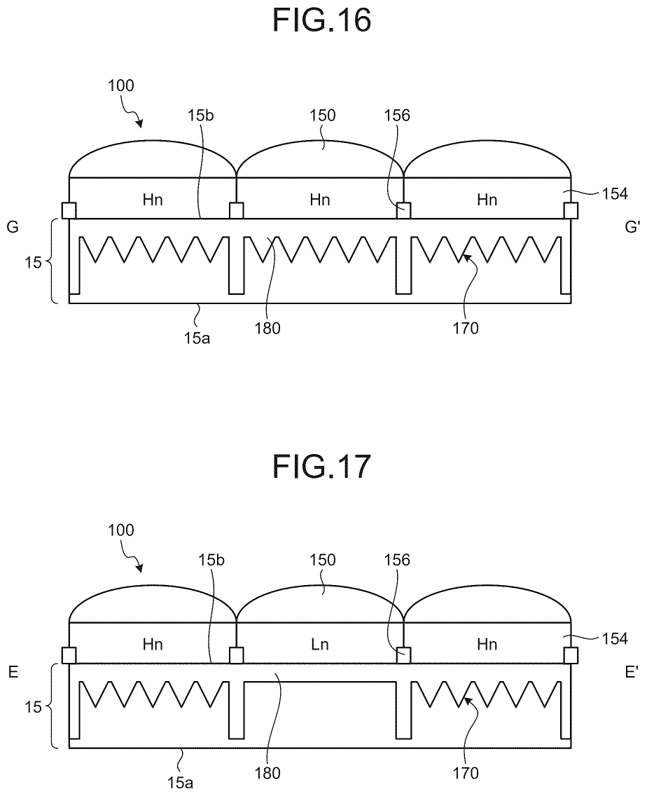

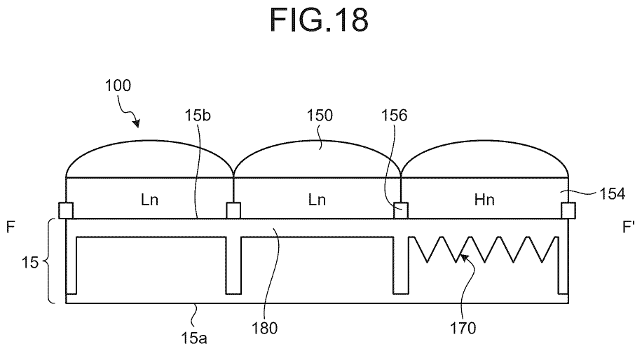

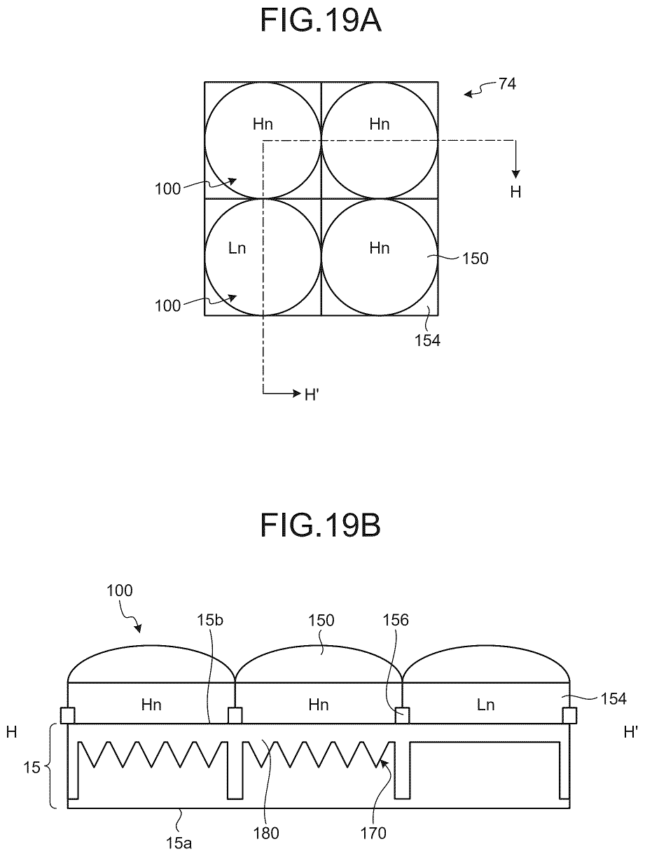

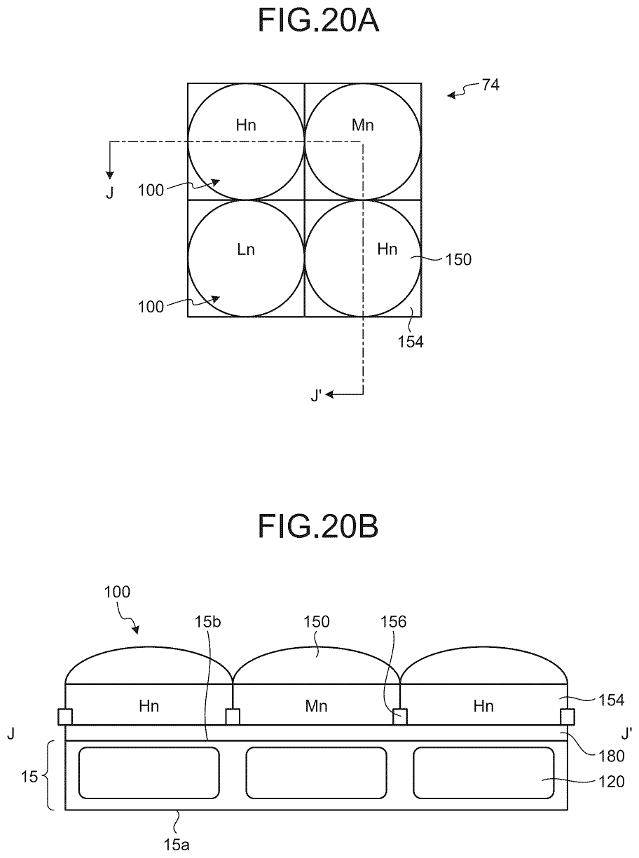

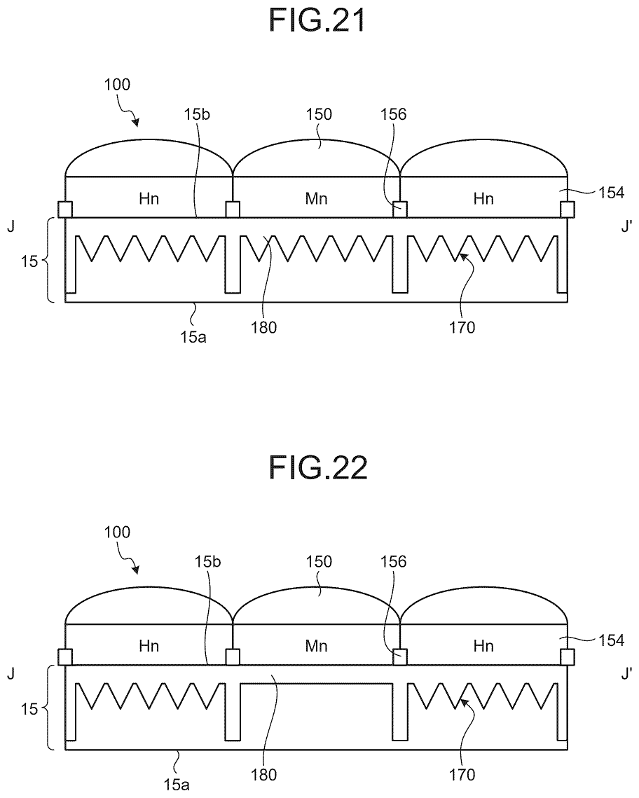

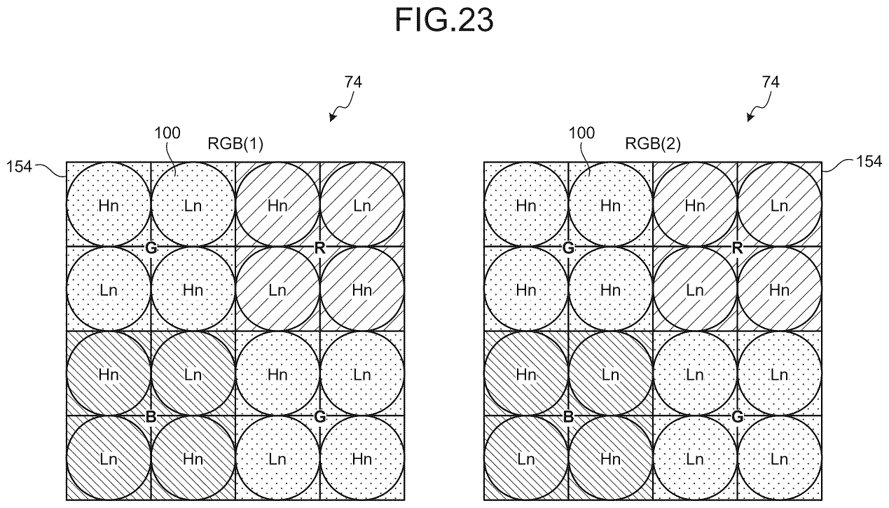

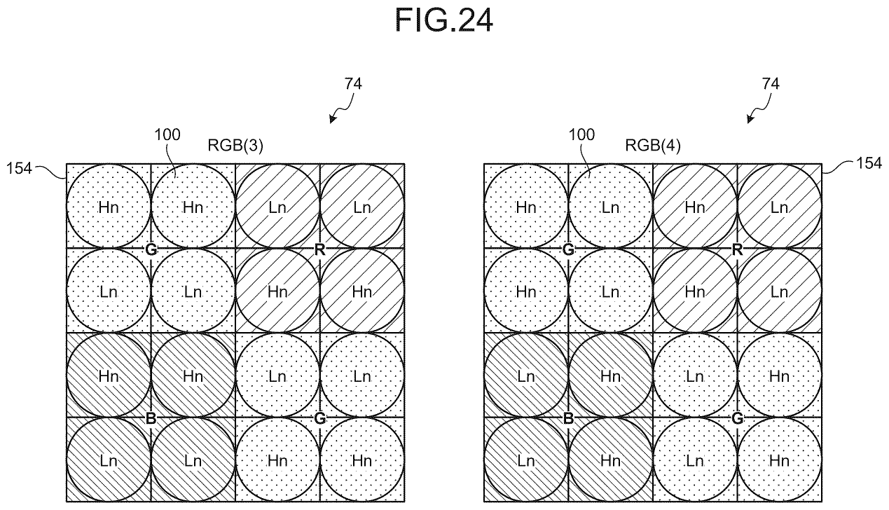

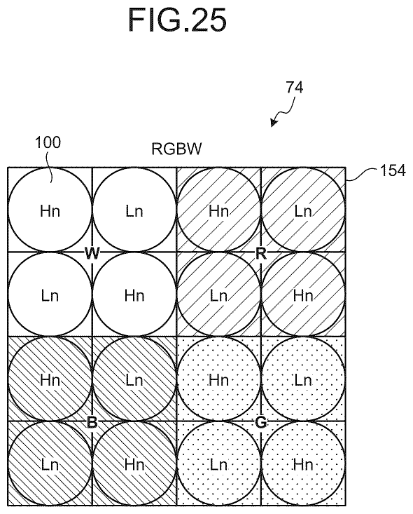

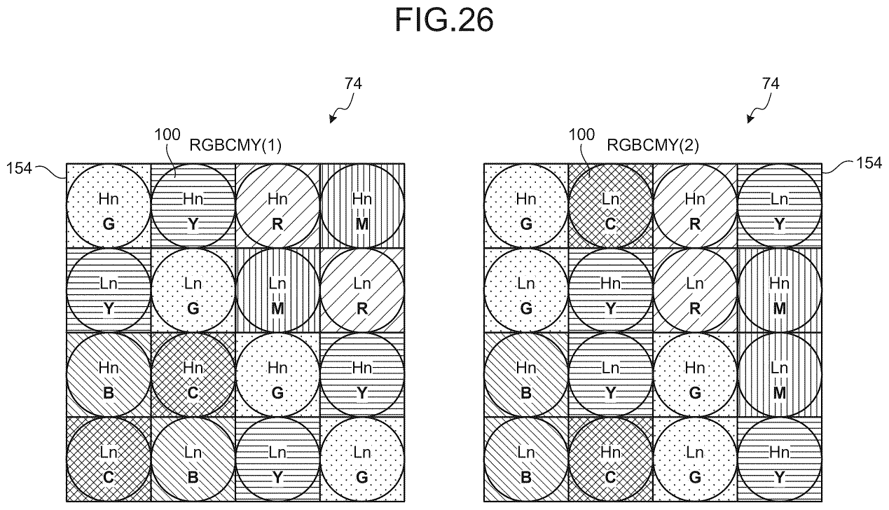

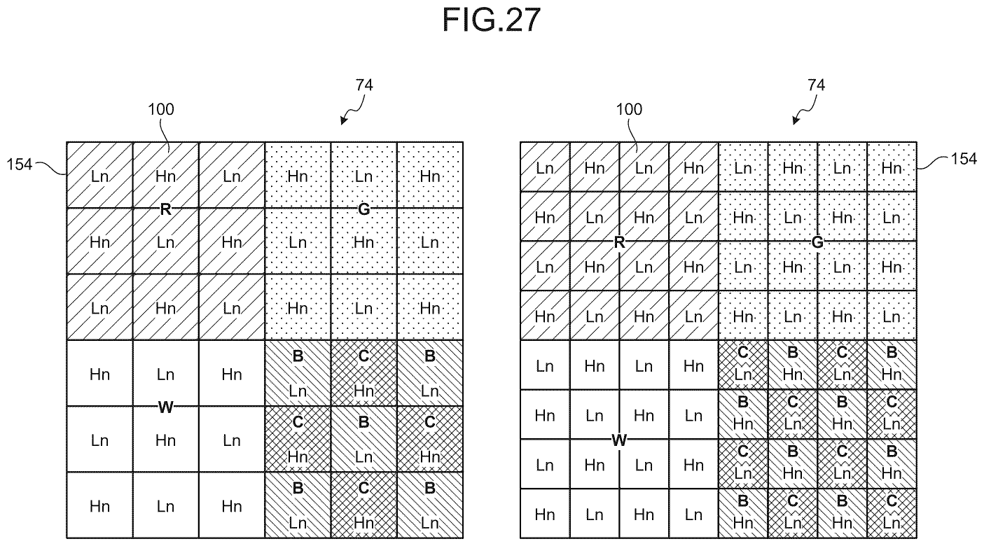

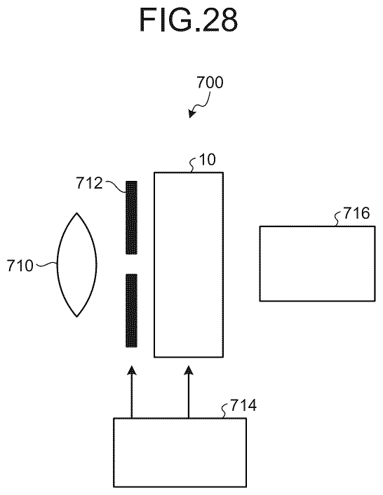

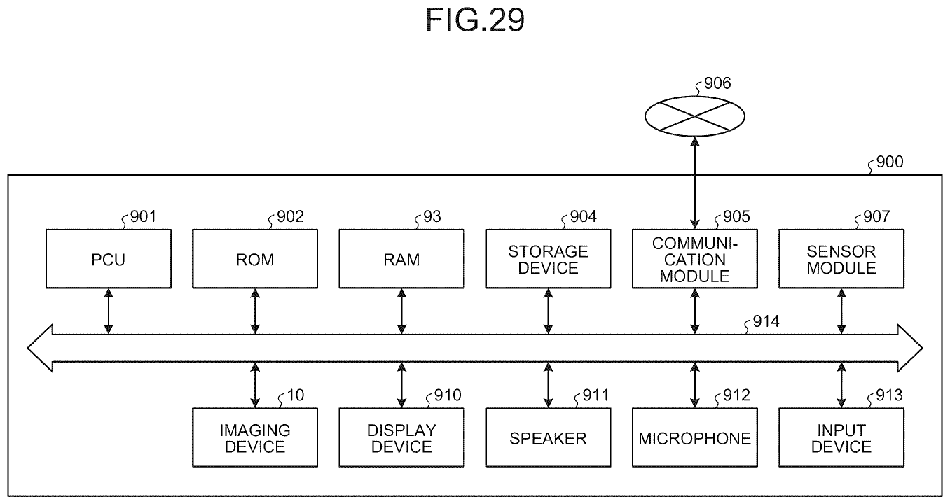

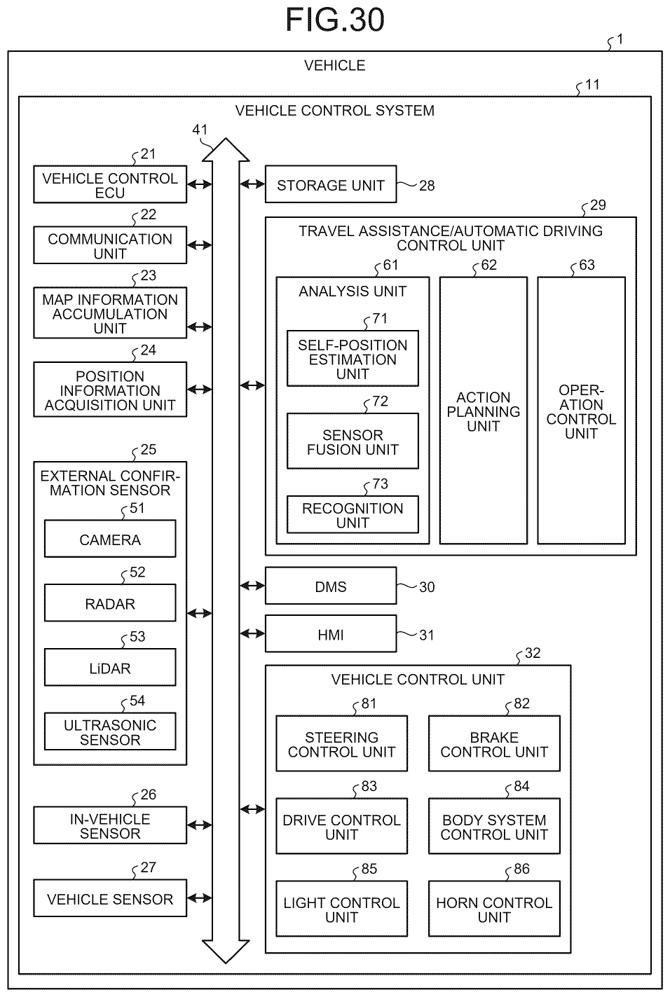

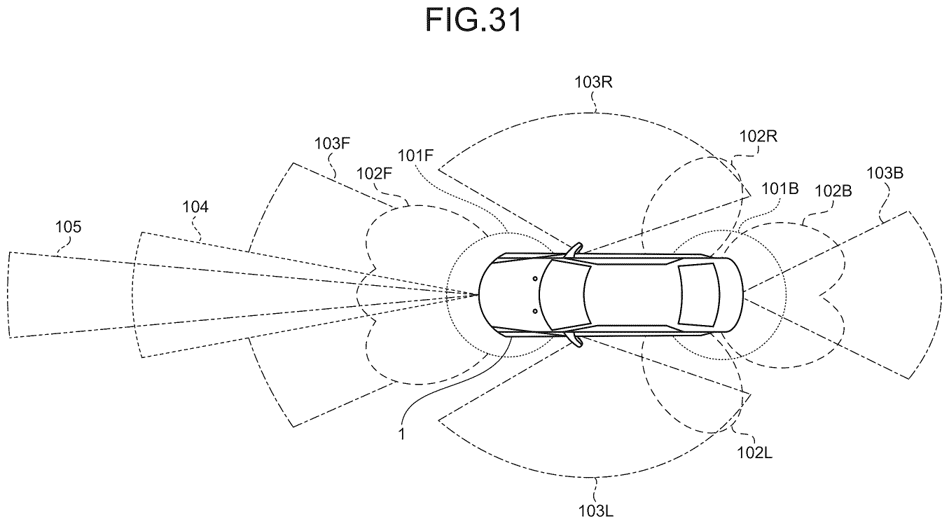

FIG. 12B is an illustrative diagram illustrating a cross-sectional configuration example of the color filter unit 74 according to the modification 3 of the fifth embodiment of the present disclosure.

FIG. 13A is an illustrative diagram illustrating a cross-sectional configuration example of a color filter unit 74 according to a sixth embodiment of the present disclosure.

FIG. 13B is a circuit diagram of an imaging element 100 according to the sixth embodiment of the present disclosure.

FIG. 14 is an illustrative diagram illustrating a cross-sectional configuration example of a color filter unit 74 according to a seventh embodiment of the present disclosure.

FIG. 15 is an illustrative diagram illustrating a cross-sectional configuration example of a color filter unit 74 according to a modification 1 of the seventh embodiment of the present disclosure.

FIG. 16 is an illustrative diagram illustrating a cross-sectional configuration example of a color filter unit 74 according to a modification 2 of the seventh embodiment of the present disclosure.

FIG. 17 is an illustrative diagram illustrating a cross-sectional configuration example of a color filter unit 74 according to an eighth embodiment of the present disclosure.

FIG. 18 is an illustrative diagram illustrating a cross-sectional configuration example of a color filter unit 74 according to a modification 1 of the eighth embodiment of the present disclosure.

FIG. 19A is an illustrative diagram illustrating a planar configuration example of a color filter unit 74 according to a modification 2 of the eighth embodiment of the present disclosure.

FIG. 19B is an illustrative diagram illustrating a cross-sectional configuration example of the color filter unit 74 according to the modification 2 of the eighth embodiment of the present disclosure.

FIG. 20A is an illustrative diagram illustrating a planar configuration example of a color filter unit 74 according to a ninth embodiment of the present disclosure.

FIG. 20B is an illustrative diagram illustrating a cross-sectional configuration example of the color filter unit 74 according to the ninth embodiment of the present disclosure.

FIG. 21 is an illustrative diagram illustrating a cross-sectional configuration example of a color filter unit 74 according to a modification 1 of the ninth embodiment of the present disclosure.

FIG. 22 is an illustrative diagram illustrating a cross-sectional configuration example of a color filter unit 74 according to a modification 2 of the ninth embodiment of the present disclosure.

FIG. 23 is an illustrative diagram (1) illustrating a planar configuration example of a color filter unit 74 according to a tenth embodiment of the present disclosure.

FIG. 24 is an illustrative diagram (2) illustrating the planar configuration example of the color filter unit 74 according to the tenth embodiment of the present disclosure.

FIG. 25 is an illustrative diagram (1) illustrating a planar configuration example of a color filter unit 74 according to an eleventh embodiment of the present disclosure.

FIG. 26 is an illustrative diagram (2) illustrating the planar configuration example of the color filter unit 74 according to the eleventh embodiment of the present disclosure.

FIG. 27 is an illustrative diagram (3) illustrating the planar configuration example of the color filter unit 74 according to the eleventh embodiment of the present disclosure.

FIG. 28 is an explanatory diagram illustrating an example of a schematic functional configuration of a camera.

FIG. 29 is a block diagram illustrating an example of a schematic functional configuration of a smartphone.

FIG. 30 is a block diagram illustrating a configuration example of a vehicle control system.

FIG. 31 is a diagram illustrating an example of a sensing region.

### DESCRIPTION OF EMBODIMENTS

Hereinafter, preferred embodiments of the present disclosure are described in detail with reference to the accompanying drawings. Note that, in the present specification and the drawings, components having substantially the same functional configuration are denoted by the same reference numerals, and redundant description is omitted. In the present specification and the drawings, a plurality of components having substantially the same or similar functional configuration might be distinguished by attaching different alphabets after the same reference numeral. However, in a case where it is not particularly necessary to distinguish each of a plurality of components having substantially the same or similar functional configuration, only the same reference numeral is attached.

The drawings referred to in the following description are drawings for promoting the description and understanding of one embodiment of the present disclosure, and shapes, dimensions, ratios and the like illustrated in the drawings might be different from actual ones for the sake of clarity. Moreover, the imaging device illustrated in the drawings can be appropriately modified in design in consideration of the following description and known technologies.

Note that, the description will be given in the following order.
1. Schematic Configuration of Imaging Device
1.1 Imaging Device
1.2 Imaging Element
2. Background Leading to Creation of Embodiment of Present Disclosure
3. First Embodiment
3.1 Detailed Configuration
3.2 Modification 1
3.3 Modification 2
4. Second Embodiment
5. Third Embodiment
6. Fourth Embodiment
7. Fifth Embodiment
7.1 Detailed Configuration
7.2 Modification
8. Sixth Embodiment
9. Seventh Embodiment
9.1 Detailed Configuration
9.2 Modification 1
9.3 Modification 2
10. Eighth Embodiment
10.1 Detailed Configuration
10.2 Modification 1
10.3 Modification 2
11. Ninth Embodiment
11.1 Detailed Configuration
11.2 Modification 1
11.3 Modification 2
12. Tenth Embodiment
13. Eleventh Embodiment
14. Summary
15. Application Example
15.1 Application Example to Camera
15.2 Application Example to Smartphone
15.3 Application Example to Moving Device Control System
16. Supplement

### <<1. Schematic Configuration of Imaging Device>>

### <1.1 Imaging Device>

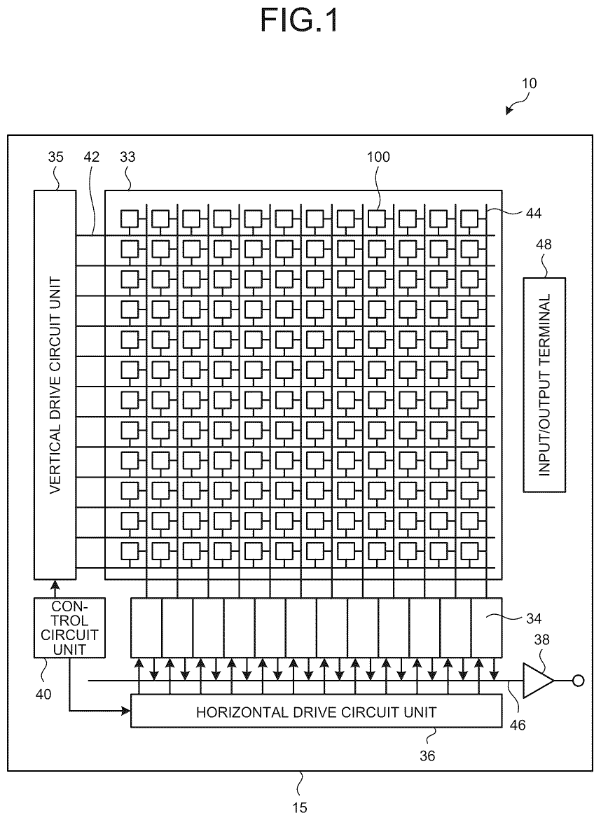

First, a schematic configuration of an imaging device 10 according to an embodiment of the present disclosure is described with reference to FIG. 1. FIG. 1 is an illustrative diagram illustrating a planar configuration example of the imaging device 10 according to the embodiment of the present disclosure. As illustrated in FIG. 1, the imaging device 10 according to the embodiment of the present disclosure includes, for example, a pixel array unit 33 in which a plurality of imaging elements (pixels) 100 is arranged in a matrix on a semiconductor substrate 15 made of silicon, and a peripheral circuit unit provided so as to enclose the pixel array unit 33. Moreover, the above-described imaging device 10 includes, as the peripheral circuit unit, a column signal processing circuit unit 34, a vertical drive circuit unit 35, a horizontal drive circuit unit 36, an output circuit unit 38, a control circuit unit 40 and the like. Hereinafter, each block of the imaging device 10 is described in detail.

### (Pixel Array Unit 33)

The pixel array unit 33 includes a plurality of imaging elements 100 two-dimensionally arranged in a matrix in a row direction and in a column direction on the semiconductor substrate 15. Each imaging element 100 includes a photodiode (photoelectric conversion unit) (not illustrated) that performs photoelectric conversion on incident light to generate a charge, and a plurality of pixel transistors (for example, metal-oxide-semiconductor (MOS) transistors (not illustrated). The pixel transistors include, for example, four MOS transistors including a transfer transistor, a selection transistor, a reset transistor, and an amplification transistor. Note that, a detailed structure of the imaging element 100 is to be described later.

### (Column Signal Processing Circuit Unit 34)

The column signal processing circuit unit 34 is arranged for each column of the imaging elements 100, and performs signal processing such as noise removal for each pixel column on pixel signals output from the imaging elements 100 of one row. For example, the column signal processing circuit unit 34 performs signal processing such as correlated double sampling (CDS) and analog-digital (AD) conversion in order to remove pixel-specific fixed pattern noise.

### (Vertical Drive Circuit Unit 35)

The vertical drive circuit unit 35 is formed of, for example, a shift register, selects pixel drive wiring 42, supplies a pulse for driving the imaging element 100 to the selected pixel drive wiring 42, and drives the imaging elements 100 in units of rows. That is, the vertical drive circuit unit 35 selectively scans the respective imaging elements 100 of the pixel array unit 33 sequentially in a vertical direction (up-and-down direction in FIG. 1) in units of rows, and supplies a pixel signal based on a signal charge generated depending on an amount of light received by the photoelectric conversion unit (not illustrated) of each imaging element 100 to the column signal processing circuit unit 34 to be described later via a vertical signal line 44.

### (Horizontal Drive Circuit Unit 36)

The horizontal drive circuit unit 36 is formed of, for example, a shift register, sequentially selects each of the column signal processing circuit units 34 described above by sequentially outputting horizontal scanning pulses, and causes each of the column signal processing circuit units 34 to output the pixel signal to the horizontal signal line 46.

### (Output Circuit Unit 38)

The output circuit unit 38 performs signal processing on the pixel signals sequentially supplied from each of the column signal processing circuit units 34 described above via the horizontal signal line 46 to output. The output circuit unit 38 may function as, for example, a functional unit that performs buffering, or may perform processing such as black level adjustment, column variation correction, and various pieces of digital signal processing. Note that, the buffering refers to temporal storage of pixel signals in order to compensate for differences in processing speed and transfer speed when exchanging the pixel signals. Moreover, an input/output terminal 48 is a terminal for exchanging signals with an external device.

### (Control Circuit Unit 40)

The control circuit unit 40 receives an input clock and data indicating an operation mode and the like, and outputs data such as internal information of the imaging device 10. That is, the control circuit unit 40 generates a clock signal and a control signal serving as a reference of operations of the vertical drive circuit unit 35, the column signal processing circuit unit 34, the horizontal drive circuit unit 36 and the like on the basis of a vertical synchronization signal, a horizontal synchronization signal, and a master clock. The control circuit unit 40 outputs the generated clock signal and control signal to the vertical drive circuit unit 35, the column signal processing circuit unit 34, the horizontal drive circuit unit 36 and the like.

### <1.2 Imaging Element>

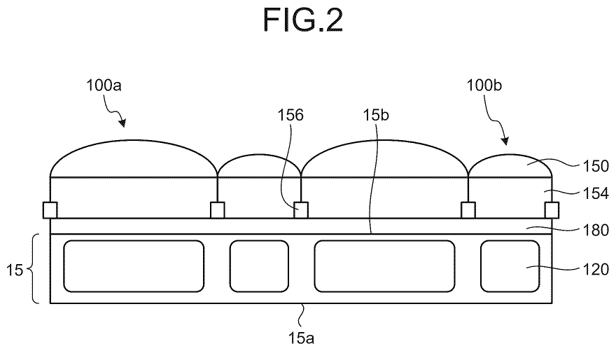

Next, a schematic configuration of the imaging element 100 according to a comparative example is described with reference to FIG. 2. FIG. 2 is an illustrative diagram illustrating a cross-sectional configuration example of the imaging element 100 according to the comparative example, and specifically corresponds to a cross section obtained by cutting the imaging element 100 in a thickness direction of the semiconductor substrate 15. Note that, the comparative example is herein intended to mean the imaging device 10 that has been examined by the present inventor before the embodiment of the present disclosure is made. The configuration of the imaging element 100 of the imaging device 10 is not limited to that illustrated in FIG. 2, and may include other configurations. Moreover, only configuration examples of elements for describing the embodiment of the present disclosure is hereinafter described, and other elements are not described.

As illustrated in FIG. 2, a plurality of imaging elements 100a and 100b is provided so as to be adjacent to each other on the semiconductor substrate 15. The imaging elements 100a and 100b mainly include an on-chip lens 150, a color filter 154, a light shielding unit 156, and an interlayer insulating film 180. Moreover, the imaging elements 100a and 100b include a photoelectric conversion unit 120 provided in the semiconductor substrate 15. Hereinafter, a stacked structure of the imaging elements 100a and 100b is to be described, and in the following description, basically, this is described in order from an upper side to a lower side in FIG. 2.

First, as illustrated in FIG. 2, each of the imaging elements 100a and 100b includes one on-chip lens 150 that is provided above a light incident surface (back surface) 15b of the semiconductor substrate 15 and condenses incident light on the photoelectric conversion unit 120 to be described later.

The incident light condensed by the on-chip lens 150 is incident on the photoelectric conversion unit 120 in the semiconductor substrate 15 via the color filter 154 provided below the on-chip lens 150. The color filter 154 can be, for example, a color filter that transmits light having a red wavelength component (for example, a wavelength of 620 nm to 750 nm), a color filter that transmits light having a green wavelength component (for example, a wavelength of 495 nm to 570 nm), a color filter that transmits light having a blue wavelength component (for example, a wavelength of 450 nm to 495 nm) and the like. The color filter 154 can be formed of, for example, a material obtained by dispersing a pigment or a dye in a transparent binder such as silicone. Note that, the color filter 154 according to the embodiment of the present disclosure is to be described later in detail.

The light shielding unit 156 is provided on the light incident surface (back surface) 15b of the semiconductor substrate 15 so as to enclose the color filter 154. Since the light shielding unit 156 is provided between the adjacent imaging elements 100a and 100b, it is possible to shield light between the adjacent imaging elements 100a and 100b. Moreover, as illustrated in FIG. 2, the interlayer insulating film 180 is provided between the semiconductor substrate 15 and the color filter 154.

The photoelectric conversion unit 120 including impurities of a first conductivity type (for example, n-type) is provided for each of the imaging elements 100a and 100b in the semiconductor substrate 15 having a second conductivity type (for example, p-type). The photoelectric conversion unit 120 can absorb the light having the red wavelength component, green wavelength component, blue wavelength component and the like incident via the color filter 154 described above to generate the charges.

In the semiconductor substrate 15, an element isolation wall (not illustrated) enclosing the imaging elements 100a and 100b and physically isolating the adjacent imaging elements 100a and 100b from each other may be provided. The element isolation wall is formed of, for example, deep trench isolation (DTI). The DTI is formed by forming a trench penetrating from the light incident surface (back surface) 15b side of the semiconductor substrate 15 to the middle of the semiconductor substrate 15 or an entire semiconductor substrate 15 in the thickness direction of the semiconductor substrate 15 and embedding the trench with a material including an oxide film or a metal film.

Moreover, the charge generated by the photoelectric conversion unit 120 is transferred to a floating diffusion unit (not illustrated) provided in a semiconductor region having the first conductivity type (for example, n-type) provided in the semiconductor substrate 15 via a transfer gate (not illustrated) provided on a front surface 15a located on a side opposite to the light incident surface (back surface) 15b of the semiconductor substrate 15. The charge transferred to the floating diffusion unit is finally output from the imaging device 10 as an imaging signal.

### <<2. Background Leading to Creation of Embodiment of Present Disclosure>>

Next, before describing the embodiment of the present disclosure, a background leading to creation of the embodiment of the present disclosure by the present inventor is described with reference to FIG. 2.

As described above, the imaging device 10 is required to further expand an illuminance range, that is, a dynamic range of a subject that can be imaged with gradation. Therefore, as illustrated in FIG. 2, a technology has been proposed in which areas of the imaging elements 100a and 100b that detect the same color light in plan view (specifically, in a case of looking from above the light incident surface 15b of the semiconductor substrate 15) are changed to intentionally generate a sensitivity difference between the imaging elements 100a and 100b, thereby expanding the dynamic range.

Specifically, in a case of imaging a low-illuminance subject, it is desirable that sensitivity of the imaging element 100 be high, and in a case of imaging a high-illuminance subject, it is desirable that a floating diffusion unit (not illustrated) be less likely to be saturated by the charge amount generated by the imaging element 100. Therefore, in the imaging device 10 according to the comparative example illustrated in FIG. 2, the imaging element 100a having an area in plan view larger than that of the imaging element 100b is provided. Since the imaging element 100a has the large area in plan view, the charge amount to be generated increases, so that this is the imaging element capable of imaging even the low-illuminance subject. In addition, in the imaging device 10, the imaging element 100b having an area in plan view smaller than that of the imaging element 100a is provided. Since the imaging element 100b has the small area in plan view, the charge amount to be generated decreases, so that the floating diffusion unit (not illustrated) is less likely to be saturated even with the high-illuminance subject. In this manner, since the imaging device 10 according to the comparative example includes the two types of imaging elements 100a and 100b, the dynamic range is expanded, in other words, it is possible to take an image with gradation over a wide illuminance range.

However, in recent years, the imaging device 10 is required to further expand the dynamic range. However, in the imaging device 10 according to the above-described comparative example, the dynamic range can be expanded basically only by increasing an area ratio between the imaging elements 100a and 100b, so that, in a case where miniaturization of the imaging element 100 progresses, there is a limit in expansion of the dynamic range. In order to expand the dynamic range, it has been proposed to provide a waveguide and the like in the imaging element 100 to improve sensitivity of a specific imaging element 100, but since the number of steps increase, it is difficult to avoid an increase in manufacturing cost of the imaging device 10.

Therefore, in view of such a situation, the present inventor has created the embodiment of the present disclosure capable of expanding the dynamic range while suppressing the increase in manufacturing cost of the imaging device 10. Hereinafter, the embodiments of the present disclosure are sequentially described in detail.

### 3. First Embodiment

### <3.1 Detailed Configuration>

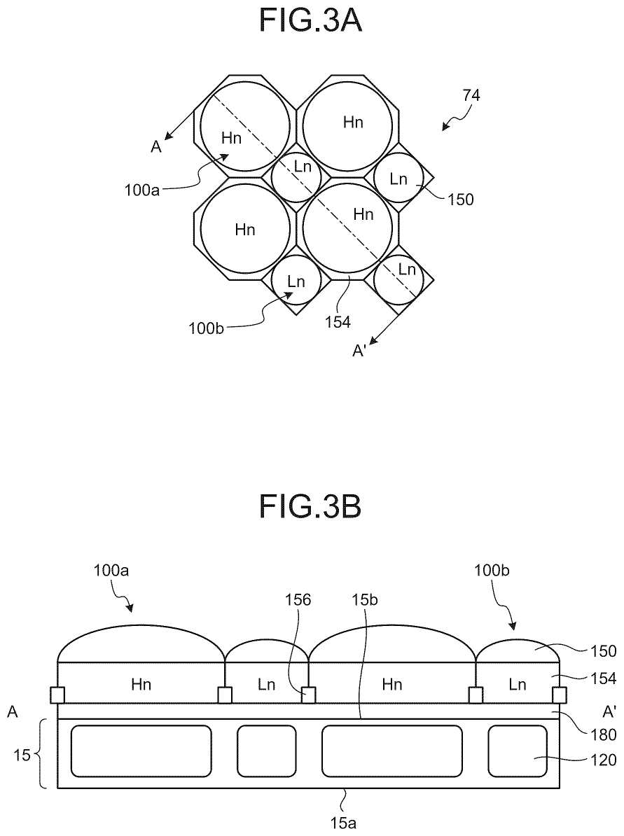

First, a first embodiment of the present disclosure is described in detail with reference to FIGS. 3A and 3B. FIG. 3A is an illustrative diagram illustrating a planar configuration example of a color filter unit 74 according to the present embodiment. FIG. 3B is an illustrative diagram illustrating a cross-sectional configuration example of the color filter unit 74 according to the present embodiment, and specifically is a cross-sectional view taken along line A-A′ in FIG. 3A.

In the present embodiment also, as described above, the color filter 154 is provided corresponding to one imaging element 100, and a plurality of imaging elements 100 is arrayed in the pixel array unit 33 according to a predetermined rule. Therefore, in the present embodiment, a predetermined number of color filters 154 are regularly arrayed to form one color filter unit (unit region) 74. Moreover, a color filter array (not illustrated) corresponding to an entire pixel array unit 33 is formed as a whole by arraying a plurality of color filter units (unit regions) 74 in a two-dimensional array. As described above, each of the color filters 154 can transmit light of a specific wavelength (for example, red light, green light, blue light and the like) and cause the transmitted light to be incident on the photoelectric conversion unit 120 of the imaging element 100. Note that, in the present specification, a type of the color filter 154 is distinguished according to the wavelength (color) of the light transmitted through the color filter 154, and a type of the imaging element 100 corresponding to the color filter 154 is also distinguished.

Specifically, in the present embodiment, as illustrated in FIG. 3A, each of the imaging elements 100a and 100b has a polygonal shape (specifically, a quadrangle and an octagon) in plan view, and includes a circular on-chip lens. The color filters 154 corresponding to a predetermined number of (eight, in an example in FIG. 3A) imaging elements 100a and 100b are regularly arrayed to form the color filter unit (unit region) 74. In the example illustrated in FIG. 3A, each of the imaging elements 100a and 100b includes the color filter 154 of the same type (same color) that transmits light having a wavelength of a predetermined wavelength band.

Moreover, in the present embodiment, the area of the imaging element (first imaging element) 100a in plan view is larger than the area of the imaging element (second imaging element) 100b in plan view. In addition, in the present embodiment, the color filter 154 of the imaging element 100a has a refractive index higher than that of the color filter 154 of the imaging element 100b. Note that, in FIG. 3A and the drawings attached to the present specification, “Hn” is attached to the color filter 154 having a high refractive index, and “Ln” is attached to the color filter 154 having a low refractive index.

Since light has a property of traveling from the low refractive index to the high refractive index, it is determined to which of the two adjacent color filters 154 the light is easily guided depending on a relationship in refractive index of the color filters 154. That is, light is easily guided to the imaging element 100a including the color filter 154 having the high refractive index, and light is guided to the imaging element 100b including the color filter 154 having the low refractive index with difficulty. Therefore, according to the present embodiment, the sensitivity of the imaging element 100a further increases, and the sensitivity of the imaging element 100b further decreases. As a result, in the present embodiment, a sensitivity ratio larger than the sensitivity ratio caused by the area ratio between the imaging elements 100a and 100b occurs between the imaging elements 100a and 100b, so that the dynamic range of the imaging device 10 can be expanded.

As illustrated in FIG. 3B, in the present embodiment also, the imaging elements 100a and 100b are provided so as to be adjacent to each other on the semiconductor substrate 15. The imaging elements 100a and 100b mainly include an on-chip lens 150, a color filter 154, a light shielding unit 156, and an interlayer insulating film 180. Moreover, the imaging elements 100a and 100b further include the photoelectric conversion unit 120 provided in the semiconductor substrate 15.

Specifically, as illustrated in FIG. 3B, each of the imaging elements 100a and 100b includes one on-chip lens 150 that is provided above the light incident surface (back surface) 15b of the semiconductor substrate 15 and condenses the incident light on the photoelectric conversion unit 120.

In the present embodiment also, the incident light condensed by the on-chip lens 150 is incident on the photoelectric conversion unit 120 via the color filter 154 provided below the on-chip lens 150. The color filter 154 can be formed of, for example, a material obtained by dispersing a pigment or a dye in a transparent binder such as silicone.

In the present embodiment, as described above, the color filter 154 of the imaging element 100a has the refractive index higher than that of the color filter 154 of the imaging element 100b. The refractive index of the color filter 154 can be adjusted by including photosensitive particles or adjusting a content of the photosensitive particles. For example, in the present embodiment, the color filter 154 of the imaging element 100a is allowed to include the photosensitive particles, and the color filter 154 of the imaging element 100b is not allowed to include the photosensitive particles. Alternatively, in the present embodiment, for example, the density of the photosensitive particles of the color filter 154 of the imaging element 100b may be made lower than the density of the photosensitive particles of the color filter 154 of the imaging element 100a. More specifically, for example, by allowing the color filter 154 of the imaging element 100a to include titanium oxide (TiO₂) particles or zinc oxide (ZnO) particles as the photosensitive particles, the refractive index of the color filter 154 can be set to about 1.7 to 2.2.

The photosensitive particles described above can be formed of at least one selected from a group including titanium oxide particles, zirconium oxide (ZrO₂) particles, zinc oxide particles, and nanodiamond particles. For example, an amount of photosensitive particles included in a minute color filter 154 can be measured by a transmission electron microscope (TEM) device equipped with Auger electron spectroscopy (AES) capable of measuring an amount of metal components on an outermost surface of a local region at a level of several 0 nm in diameter or energy dispersive X-ray analysis (EDX) capable of measuring the amount of metal components in a local region at a level of several nm in diameter.

In the present embodiment also, the light shielding unit 156 is provided above the light incident surface (back surface) 15b of the semiconductor substrate 15 so as to enclose the color filter 154. Since the light shielding unit 156 is provided between the adjacent imaging elements 100a and 100b, this shields light between the adjacent imaging elements 100a and 100b. Moreover, in the present embodiment also, the interlayer insulating film 180 is provided between the semiconductor substrate 15 and the color filter 154.

Moreover, in the present embodiment also, the photoelectric conversion unit 120 including impurities of the first conductivity type different from the second conductivity type is provided for each of the imaging elements 100a and 100b in the semiconductor substrate 15 having the second conductivity type. The photoelectric conversion unit 120 can absorb light incident via the above-described color filter 154 to generate charges.

In the semiconductor substrate 15, an element isolation wall (not illustrated) enclosing the imaging elements 100a and 100b and physically isolating the adjacent imaging elements 100a and 100b from each other may be provided. The element isolation wall is formed of, for example, DTI. The DTI is formed by forming a trench penetrating from the light incident surface (back surface) 15b side of the semiconductor substrate 15 to the middle of the semiconductor substrate 15 or an entire semiconductor substrate 15 in the thickness direction of the semiconductor substrate 15 and embedding the trench with a material including an oxide film or a metal film.

Moreover, in the present embodiment also, the charge generated by the photoelectric conversion unit 120 is transferred to a floating diffusion unit (not illustrated) provided in a semiconductor region having the first conductivity type provided in the semiconductor substrate 15 via a transfer gate (not illustrated) provided on the front surface 15a located on a side opposite to the light incident surface 15b of the semiconductor substrate 15. The charge transferred to the floating diffusion unit is finally output from the imaging device 10 as an imaging signal.

As described above, in the present embodiment, by making the refractive index of the color filter 154 of the imaging element 100a higher than that of the color filter 154 of the imaging element 100b, light is easily guided to the imaging element 100a including the color filter 154 having the high refractive index, and light is guided to the imaging element 100b including the color filter 154 having the low refractive index with difficulty. Therefore, according to the present embodiment, the sensitivity of the imaging element 100a further increases, and the sensitivity of the imaging element 100b further decreases. As a result, in the present embodiment, a sensitivity ratio larger than the sensitivity ratio caused by the area ratio between the imaging elements 100a and 100b occurs between the imaging elements 100a and 100b, so that the dynamic range of the imaging device 10 can be expanded.

### <3.2 Modification 1>

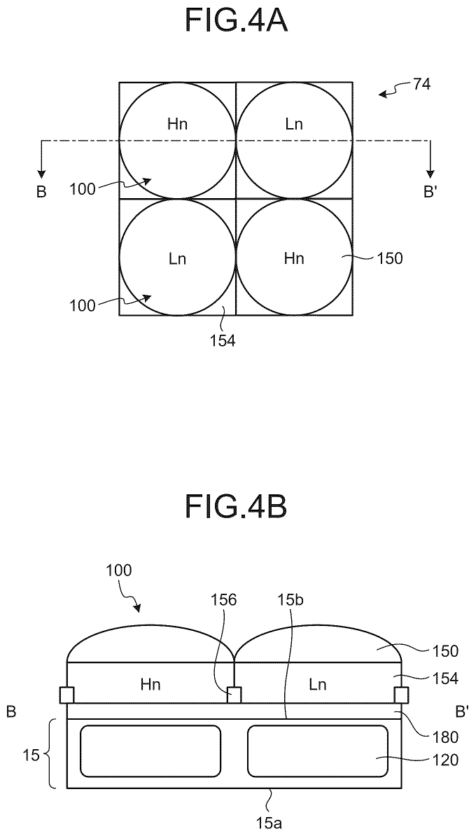

Next, a modification 1 of the present embodiment is described in detail with reference to FIGS. 4A and 4B. FIG. 4A is an illustrative diagram illustrating a planar configuration example of a color filter unit 74 according to the present modification. FIG. 4B is an illustrative diagram illustrating a cross-sectional configuration example of the color filter unit 74 according to the present modification, and specifically is a cross-sectional view taken along line B-B′ in FIG. 4A.

In the present embodiment described above, the color filters 154 having different refractive indexes are used in the imaging elements 100a and 100b having different areas in plan view in order to further increase the sensitivity ratio. In contrast, in the present modification, by applying the color filters 154 having different refractive indexes to the imaging elements 100 having the same area (size), a sensitivity ratio is created between the imaging elements 100, and a dynamic range of the imaging device 10 is expanded.

Specifically, in the present modification, as illustrated in FIG. 4A, each of the imaging elements 100 has a square shape in plan view, and includes a circular on-chip lens. Moreover, as illustrated in FIG. 4A, in the present modification, the color filter unit (unit region) 74 formed by arraying the color filters 154 in two rows and two columns is formed. Note that, in the present disclosure, the color filter unit 74 is not limited to include the color filters 154 arrayed in two rows and two columns as illustrated in FIG. 4A.

Moreover, in the present modification, the imaging element 100 includes the color filters 154 having different refractive indexes as illustrated in FIGS. 4A and 4B (in FIGS. 4A and 4B, “Hn” is attached to the color filter 154 having the high refractive index, and “Ln” is attached to the color filter 154 having the low refractive index.). Note that, in the present modification, each of the imaging elements 100 includes the color filter 154 of the same type (same color) that transmits light having a wavelength of a predetermined wavelength band.

As described above, according to the present modification, by making the refractive index of the color filter 154 of some imaging elements 100 higher than that of the color filter 154 of the remaining imaging elements 100, light is easily guided to the imaging element 100 including the color filter 154 having the high refractive index, and light is guided to the imaging element 100 including the color filter 154 having the low refractive index with difficulty. Therefore, according to the present embodiment, the sensitivity ratio occurs between the imaging elements 100 even with the imaging elements 100 of the same area in plan view, so that the dynamic range of the imaging device 10 can be expanded.

### <3. 3 Modification 2>

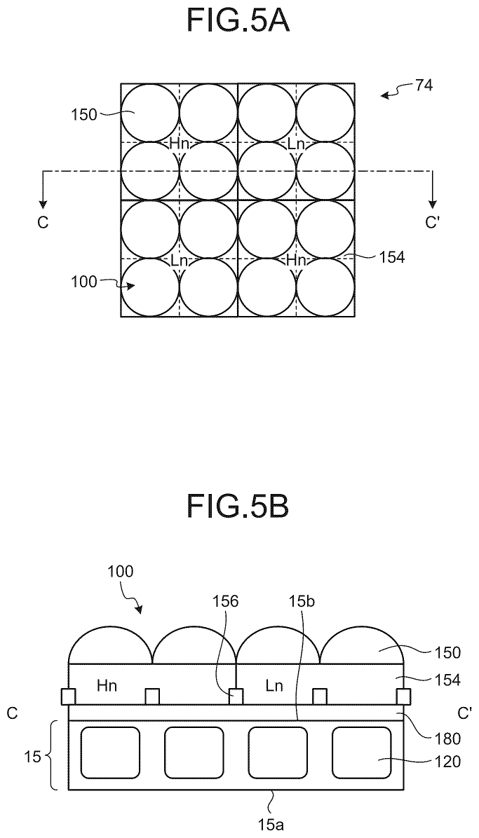

Next, a modification 2 of the present embodiment is described in detail with reference to FIGS. 5A and 5B. FIG. 5A is an illustrative diagram illustrating a planar configuration example of a color filter unit 74 according to the present modification. FIG. 5B is an illustrative diagram illustrating a cross-sectional configuration example of the color filter unit 74 according to the present modification, and specifically is a cross-sectional view taken along line C-C′ in FIG. 5A.

Specifically, in the present modification, as illustrated in FIG. 5A, each imaging element 100 of the modification 1 described above may include four minute imaging elements 100 arrayed in two rows and two columns. Note that, in the present disclosure, as long as each imaging element 100 of the modification 1 described above includes a plurality of minute imaging elements 100 arrayed according to a predetermined rule, each imaging element is not limited to include four minute imaging elements 100 arrayed in two rows and two columns illustrated in FIGS. 5A and 5B.

### 4. Second Embodiment

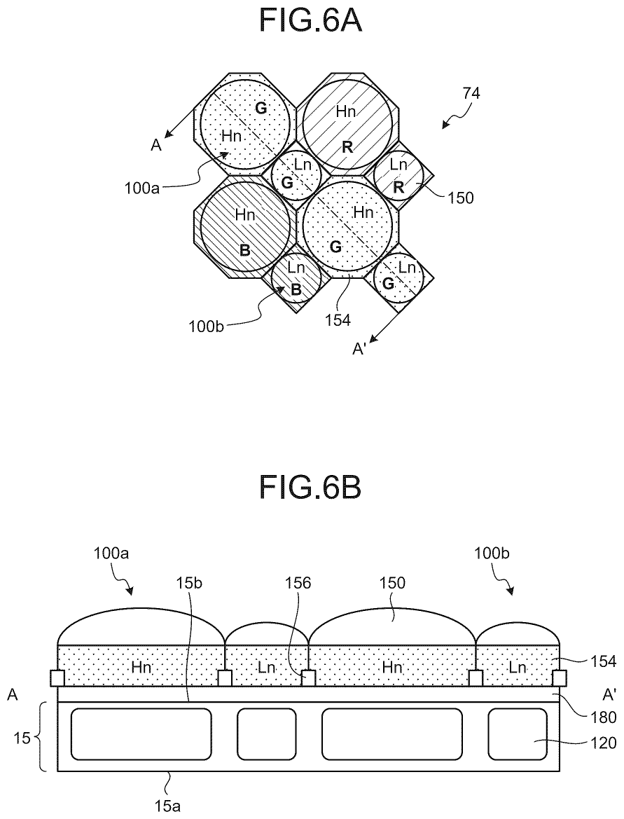

First, a second embodiment of the present disclosure is described in detail with reference to FIGS. 6A and 6B. FIG. 6A is an illustrative diagram illustrating a planar configuration example of a color filter unit 74 according to the present embodiment. FIG. 6B is an illustrative diagram illustrating a cross-sectional configuration example of the color filter unit 74 according to the present embodiment, and specifically is a cross-sectional view taken along line A-A′ in FIG. 6A.

In the present embodiment, as illustrated in FIG. 6A, each of the imaging elements 100a and 100b has a polygonal shape (specifically, a quadrangle and an octagon) in plan view, and includes a circular on-chip lens as in the first embodiment. However, in the present embodiment, unlike the first embodiment, as illustrated in FIG. 4A, each of the imaging elements 100a and 100b includes the color filters 154 of different types (colors) that transmit light having wavelengths of different predetermined wavelength bands. More specifically, the color filter 154 is, for example, a color filter that transmits light having a red wavelength component, a color filter that transmits light having a green wavelength component, and a color filter that transmits light having a blue wavelength component. That is, the present embodiment can be said to be a modification of the first embodiment to an RGB compatible imaging device capable of detecting red light, green light, and blue light. Note that, in the drawings attached to the present specification, the color filter 154 that transmits light having a red wavelength component is indicated by “R”, the color filter 154 that transmits light having a green wavelength component is indicated by “G”, and the color filter 154 that transmits light having a blue wavelength component is indicated by “B”.

Moreover, also in the present embodiment, similarly to the first embodiment, in the imaging elements 100a and 100b of the same type including the color filters 154 of the same type (color), the imaging element (first imaging element) 100a has a larger area than the imaging element (second imaging element) 100b. In addition, in the present embodiment also, the color filter 154 of the imaging element 100a has a refractive index higher than that of the color filter 154 of the imaging element 100b.

Therefore, in the present embodiment, by making the refractive index of the color filter 154 of the imaging element 100a higher than that of the color filter 154 of the imaging element 100b in the imaging elements 100a and 100b of the same type, light is easily guided to the imaging element 100a including the color filter 154 having the high refractive index, and light is guided to the imaging element 100b including the color filter 154 having the low refractive index with difficulty. Therefore, according to the present embodiment, the sensitivity of the imaging element 100a further increases, and the sensitivity of the imaging element 100 further decreases. As a result, in the present embodiment, a sensitivity ratio larger than the sensitivity ratio caused by the area ratio between the imaging elements 100a and 100b of the same type occurs between the imaging elements 100a and 100b, so that the dynamic range of the imaging device 10 can be expanded.

### 5. Third Embodiment

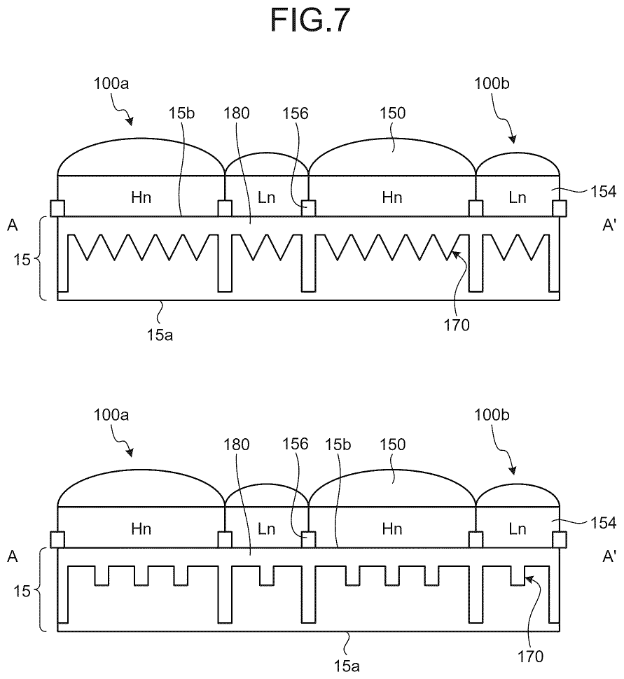

Next, a third embodiment of the present disclosure is described in detail with reference to FIG. 7. FIG. 7 is an illustrative diagram illustrating a cross-sectional configuration example of a color filter unit 74 according to the present embodiment, and specifically is a cross-sectional view taken along line A-A′ in FIG. 3A or 6A. The present embodiment is an embodiment in which roughness is provided on the light incident surface 15b of the semiconductor substrate 15 in the configuration according to the first and second embodiments described above.

Specifically, in the present embodiment, imaging elements 100a and 100b include a photoelectric conversion unit 120 (not illustrated in FIG. 7) including impurities of a first conductivity type different from a second conductivity type in the semiconductor substrate 15 having the second conductivity type, for example, as in the first and second embodiments. Moreover, in the present embodiment, as illustrated in FIG. 7, a surface on the light incident surface 15b side of the semiconductor substrate 15 located above the photoelectric conversion unit 120 of each of the imaging elements 100a and 100b has roughness 170. In the present embodiment, by providing the roughness 170 on the light incident surface 15b side, reflection of light on the light incident surface 15b of the semiconductor substrate 15 is suppressed, and an optical path length is extended so that light can further reach the photoelectric conversion unit 120. Specifically, in an upper part in FIG. 7, the surface on the light incident surface 15b side of the semiconductor substrate 15 is provided with the roughness 170 having an acute angle, and in a lower part in FIG. 7, the surface on the light incident surface 15b side of the semiconductor substrate 15 is provided with rectangular roughness 170. Moreover, in the present embodiment, an interlayer insulating film 180 may be provided between the semiconductor substrate 15 and a color filter 154. Note that, in FIG. 7 and the drawings subsequent to FIG. 7 (the drawings illustrating the roughness 170), for convenience, the semiconductor substrate 15 includes the interlayer insulating film 180 covering the roughness 170, and an outermost surface covered with the interlayer insulating film 180 is the light incident surface 15b.

As described above, in the present embodiment, by providing the roughness 170 on the light incident surface 15b side, reflection of light on the light incident surface 15b of the semiconductor substrate 15 is suppressed, and the optical path length is extended so that light can further reach the photoelectric conversion unit 120. As a result, according to the present embodiment, since light easily reaches the photoelectric conversion unit 120, photoelectric conversion efficiency of the imaging elements 100a and 100b increases. In addition, according to the present embodiment, since light is suppressed from traveling to the adjacent imaging elements 100a and 100b due to reflection, occurrence of color mixing can be suppressed.

### 6. Fourth Embodiment

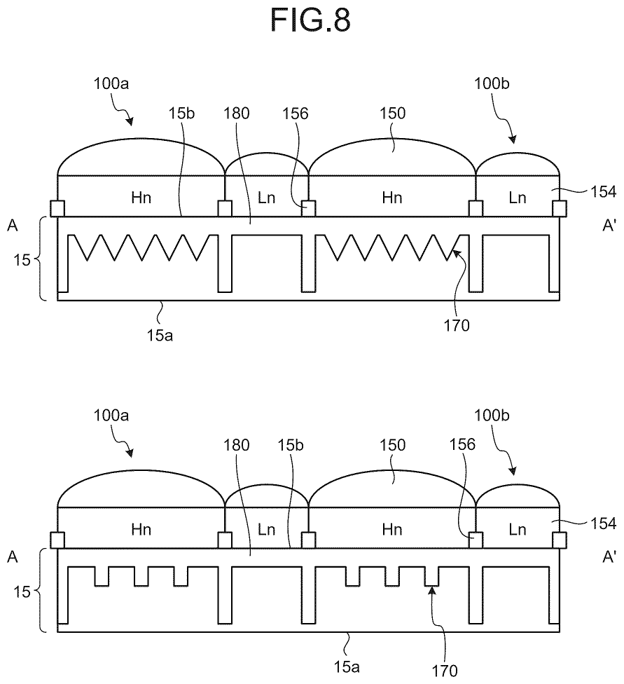

Next, a fourth embodiment of the present disclosure is described in detail with reference to FIG. 8. FIG. 8 is an illustrative diagram illustrating a cross-sectional configuration example of a color filter unit 74 according to the present embodiment, and specifically is a cross-sectional view taken along line A-A′ in FIG. 3A or 6A. The present embodiment is an example in which the roughness 170 is provided only on the surface on the light incident surface 15b side of the semiconductor substrate 15 of the imaging element 100a in the configuration according to the first and second embodiments.

Specifically, according to the present embodiment, as illustrated in FIG. 8, the surface on the light incident surface 15b side of the semiconductor substrate 15 located above a photoelectric conversion unit 120 of the imaging element 100a has the roughness 170. In contrast, the surface on the light incident surface 15b side of the semiconductor substrate 15 located above the photoelectric conversion unit 120 of the imaging element 100b is flat. In the present embodiment, by providing the roughness 170 on the light incident surface 15b side of the imaging element 100a, reflection of light on the light incident surface 15b of the semiconductor substrate 15 is suppressed, and an optical path length is extended so that light can further reach the photoelectric conversion unit 120. Specifically, in an upper part in FIG. 8, only the surface on the light incident surface 15b side of the semiconductor substrate 15 of the imaging element 100a is provided with the roughness 170 having an acute angle, and in a lower part in FIG. 8, only the surface on the light incident surface 15b side of the semiconductor substrate 15 of the imaging element 100a is provided with rectangular roughness 170.

As described above, in the present embodiment, by providing the roughness 170 only on the surface on the light incident surface 15b side of the semiconductor substrate 15 of the imaging element 100a including the color filter 154 having a high refractive index, reflection of light on the light incident surface 15b of the semiconductor substrate 15 is suppressed, and the optical path length is extended, so that light can further reach the photoelectric conversion unit 120. Therefore, according to the present embodiment, since light easily reaches the photoelectric conversion unit 120 of the imaging element 100a including the color filter 154 having a high refractive index, the sensitivity of the imaging element 100a further increases. As a result, in the present embodiment, a sensitivity ratio between the imaging elements 100a and 100b further increases, so that a dynamic range of the imaging device 10 can be further expanded.

### 7. Fifth Embodiment

### <7.1 Detailed Configuration>

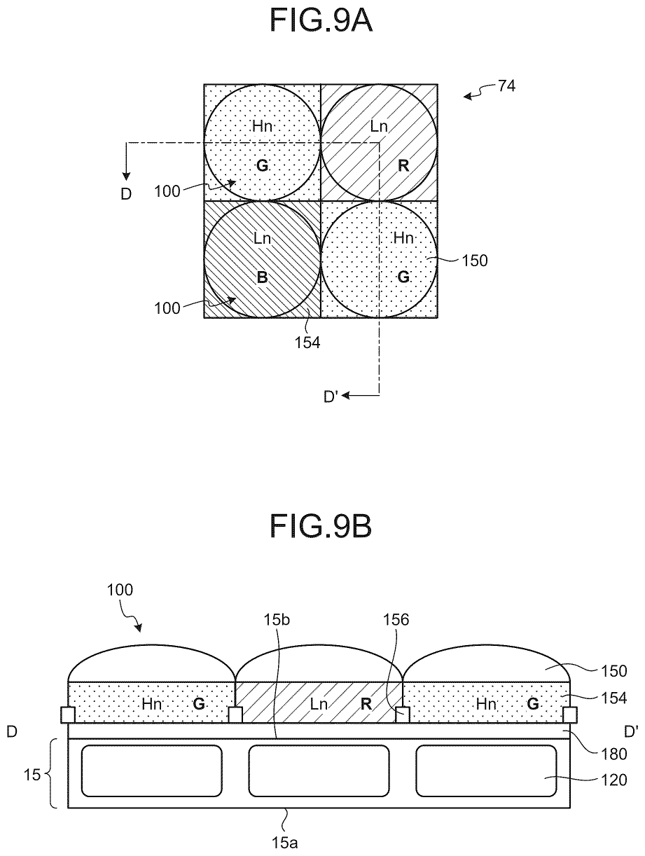

First, a fifth embodiment of the present disclosure is described in detail with reference to FIGS. 9A and 9B. FIG. 9A is an illustrative diagram illustrating a planar configuration example of a color filter unit 74 according to the present embodiment. FIG. 9B is an illustrative diagram illustrating a cross-sectional configuration example of the color filter unit 74 according to the present embodiment, and specifically is a cross-sectional view taken along line D-D′ in FIG. 9A.

In order to be able to reproduce a color closer to a color when viewed with human eyes, an imaging device 10 preferably detects green light with higher precision. Therefore, it is required to improve the sensitivity of the imaging element 100 corresponding to a color filter 154 that transmits green light. Moreover, in the imaging device 10 according to the conventional technology, the refractive index of the color filter 154 has not been studied in detail, so that the color filter 154 that transmits red light having a refractive index higher than that of the color filter 154 that transmits green light is often used. Therefore, in the imaging device 10 according to the conventional technology, the sensitivity of the imaging element 100 that detects green light is lower than that of the imaging element 100 that detects red light.

Therefore, in the present embodiment, the sensitivity of the imaging element 100 including the color filter 154 that transmits green light in the color filter unit 74 including the color filters 154 arrayed in the Bayer array is improved by applying the color filter 154 having a high refractive index.

Specifically, as illustrated in FIG. 9A, the color filter unit 74 includes a plurality of color filters 154 arrayed in two rows and two columns in a two-dimensional manner according to the Bayer array. The Bayer array is an array pattern in which the color filters 154 that transmit light having a green wavelength component are arranged in a checkered pattern, and the color filters 154 that transmit light having a red wavelength component and the color filters 154 that transmit light having a blue wavelength component are alternately arranged in the remaining portion for each line. More specifically, in the example in FIG. 9A, the color filters 154 that transmit green light are arranged on upper left and lower right parts of the color filter unit 74, and the color filter 154 that transmits red light is arranged on an upper right part of the color filter unit 74. Moreover, in the example in FIG. 9A, the color filter 154 that transmits blue light is arranged on a lower left part of the color filter unit 74.

Moreover, in the present embodiment, the refractive index of the color filter 154 that transmits light having a green wavelength component is made higher than that of the color filter 154 that transmits light having another color wavelength component (in FIGS. 9A and 9B, “Hn” is attached to the color filter 154 having the high refractive index, and “Ln” is attached to the color filter 154 having the low refractive index). As a result, in the present embodiment, the sensitivity of the imaging element 100 including the color filter 154 that transmits green light is improved.

### <7.2 Modification>

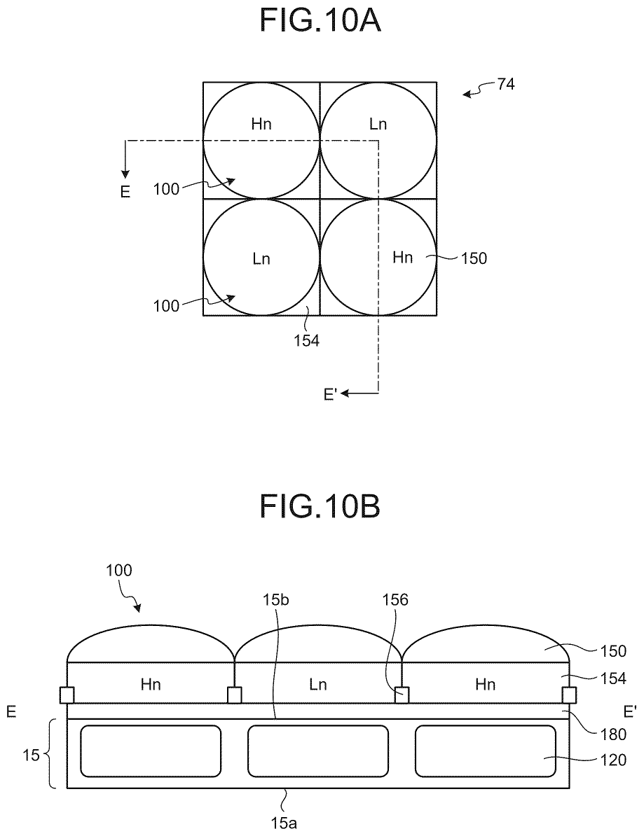

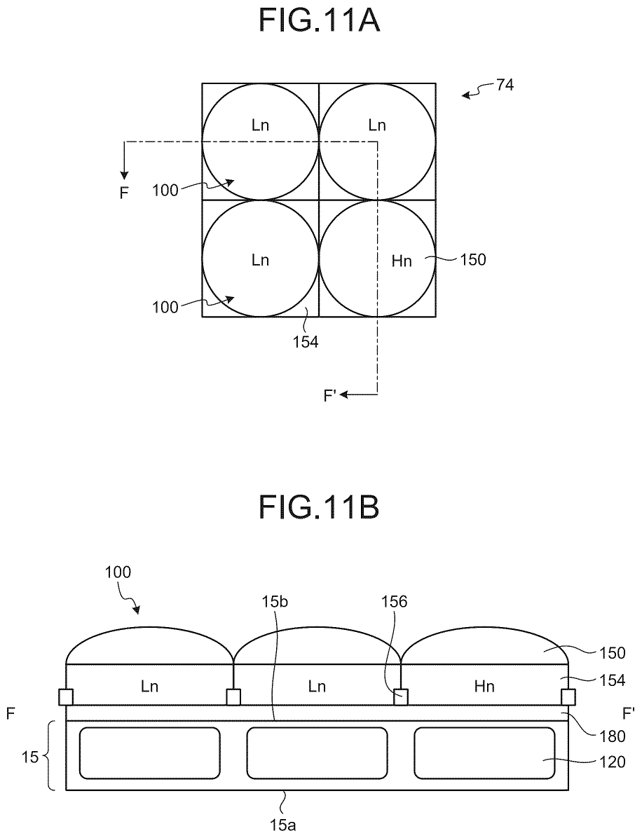

Next, a modification of the present embodiment is described in detail with reference to FIGS. 10A to 12B. FIG. 10A is an illustrative diagram illustrating a planar configuration example of the color filter unit 74 according to the present modification 1, and FIG. 10B is an illustrative diagram illustrating a cross-sectional configuration example of the color filter unit 74 according to the present modification 1; this specifically is a cross-sectional view taken along line E-E′ in FIG. 10A. FIG. 11A is an illustrative diagram illustrating a planar configuration example of the color filter unit 74 according to the present modification 2, and FIG. 11B is an illustrative diagram illustrating a cross-sectional configuration example of the color filter unit 74 according to the present modification 2; this specifically is a cross-sectional view taken along line F-F′ in FIG. 11A. Moreover, FIG. 12A is an illustrative diagram illustrating a planar configuration example of the color filter unit 74 according to the present modification 3, and FIG. 12B is an illustrative diagram illustrating a cross-sectional configuration example of the color filter unit 74 according to the present modification 3; this specifically is a cross-sectional view taken along line G-G′ in FIG. 12A.

In the present embodiment described above, the color filter 154 having the high refractive index is used in the imaging elements 100 of different types in order to increase the sensitivity of a specific imaging element 100. In contrast, in the present modification, by applying the color filters 154 having different refractive indexes, a sensitivity ratio is created between the imaging elements 100 of the same type, and a dynamic range of the imaging device 10 is expanded. Moreover, in the present modification, an example of a variation of the array of the color filter 154 having the high refractive index and the color filter 154 having the low refractive index in the color filter unit 74 including a plurality of color filters 154 arrayed in two rows and two columns in a two-dimensional manner is described.

More specifically, in the example in FIG. 10A, the color filters 154 having a high refractive index are arranged on upper left and lower right parts of the color filter unit 74, and the color filters 154 having a low refractive index are arranged on upper right and lower left parts of the color filter unit 74.

In the example in FIG. 11A, the color filters 154 having a low refractive index are arranged on upper left, upper right, and lower left parts of the color filter unit 74, and the color filter 154 having a high refractive index is arranged on a lower right part of the color filter unit 74.

In the example in FIG. 12A, the color filters 154 having a high refractive index are arranged on upper left, upper right, and lower right parts of the color filter unit 74, and the color filter 154 having a low refractive index is arranged on a lower left part of the color filter unit 74.

Note that, in the present modification, a variation of the array of the color filter 154 having the high refractive index and the color filter 154 having the low refractive index in the color filter unit 74 is not limited to the example illustrated in FIGS. 10A to 12B.

### 8. Sixth Embodiment

Next, a sixth embodiment of the present disclosure is described in detail with reference to FIGS. 13A and 13B. FIG. 13A is an illustrative diagram illustrating a cross-sectional configuration example of the color filter unit 74 according to the present embodiment, and FIG. 13B is a circuit diagram of the imaging element 100 according to the present embodiment.

In the present embodiment, in a modification 3 of the fifth embodiment, the imaging elements 100 including the color filter 154 having the high refractive index are formed as imaging elements having the same potential. Specifically, in the present embodiment, as illustrated in FIGS. 13A and 13B, the imaging elements 100 including the color filters 154 (in FIGS. 13A and 13B, represented as Hn₁, Hn₂, and Hn₃ for distinction) having the high refractive index share one photoelectric conversion unit 120 and share one floating diffusion unit (not illustrated). Therefore, according to the present embodiment, the imaging element 100 can generate a large amount of charge even in a case of imaging a low-illuminance subject or in a case of short exposure time. Therefore, according to the present embodiment, the imaging element 100 is less likely to be adversely affected by noise, and its sensitivity increases.

### 9. Seventh Embodiment

### <9.1 Detailed Configuration>

Next, a seventh embodiment of the present disclosure is described in detail with reference to FIG. 14. FIG. 14 is an illustrative diagram illustrating a cross-sectional configuration example of the color filter unit 74 according to the present embodiment, and specifically is a cross-sectional view taken along line E-E′ in FIG. 10A. In the present embodiment, a light incident surface 15b including roughness 170 is applied to the configuration according to the modification 1 of the fifth embodiment.

Specifically, in the present embodiment, as illustrated in FIG. 14, the surface on the light incident surface 15b side of the semiconductor substrate 15 located above a photoelectric conversion unit 120 of the imaging element 100 has the roughness 170.

As described above, in the present embodiment, by providing the roughness 170 on the light incident surface 15b side, reflection of light on the light incident surface 15b of the semiconductor substrate 15 is suppressed, and the optical path length is extended so that light can further reach the photoelectric conversion unit 120. As a result, according to the present embodiment, since light easily reaches the photoelectric conversion unit 120, photoelectric conversion efficiency of the imaging element 100 increases. In addition, according to the present embodiment, since light is suppressed from traveling to the adjacent imaging elements 100 due to reflection, occurrence of color mixing can be suppressed.

### <9.2 Modification 1>

Next, a modification 1 of the seventh embodiment of the present disclosure is described in detail with reference to FIG. 15. FIG. 15 is an illustrative diagram illustrating a cross-sectional configuration example of the color filter unit 74 according to the present embodiment, and specifically is a cross-sectional view taken along line F-F′ in FIG. 11A. That is, as illustrated in FIG. 15, the present modification is an example in which a light incident surface 15b having roughness 170 is applied to the configuration according to the modification 2 of the fifth embodiment.

### <9.3 Modification 2>

Next, a modification 2 of the seventh embodiment of the present disclosure is described in detail with reference to FIG. 16. FIG. 16 is an illustrative diagram illustrating a cross-sectional configuration example of the color filter unit 74 according to the present embodiment, and specifically is a cross-sectional view taken along line G-G′ in FIG. 12A. That is, as illustrated in FIG. 16, the present modification is an example in which a light incident surface 15b having roughness 170 is applied to the configuration according to the modification 3 of the fifth embodiment.

### 10. Eighth Embodiment

### <10.1 Detailed Configuration>

Next, an eighth embodiment of the present disclosure is described in detail with reference to FIG. 17. FIG. 17 is an illustrative diagram illustrating a cross-sectional configuration example of the color filter unit 74 according to the present embodiment, and specifically is a cross-sectional view taken along line E-E′ in FIG. 10A. In the present embodiment, in the configuration according to the modification 1 of the fifth embodiment, roughness 170 is provided only on a light incident surface 15b of an imaging element 100 including a color filter 154 having the high refractive index.

Specifically, as illustrated in FIG. 17, the surface on the light incident surface 15b side of the semiconductor substrate 15 located above the photoelectric conversion unit 120 of the imaging element 100 including the color filter 154 of the high refractive index includes the roughness 170. In contrast, the surface on the light incident surface 15b side of the semiconductor substrate 15 located above the photoelectric conversion unit 120 of the imaging element 100 including the color filter 154 of the low refractive index is flat.

As described above, in the present embodiment, by providing the roughness 170 only on the light incident surface 15b side of the imaging element 100 including the color filter 154 having a high refractive index, reflection of light on the light incident surface 15b of the semiconductor substrate 15 is suppressed, and the optical path length is extended, so that light can further reach the photoelectric conversion unit 120. Therefore, according to the present embodiment, since light easily reaches the photoelectric conversion unit 120 of the imaging element 100 including the color filter 154 having a high refractive index, the sensitivity of the imaging element 100 further increases. As a result, in the present embodiment, a sensitivity ratio between the imaging elements 100 further increases, so that a dynamic range of the imaging device 10 can be further expanded.

### <10.2 Modification 1>

Next, a modification 1 of the eighth embodiment of the present disclosure is described in detail with reference to FIG. 18. FIG. 18 is an illustrative diagram illustrating a cross-sectional configuration example of the color filter unit 74 according to the present embodiment, and specifically is a cross-sectional view taken along line F-F′ in FIG. 11A. In the present modification, as illustrated in FIG. 18, in the configuration according to the modification 2 of the fifth embodiment, the roughness 170 is provided only on the surface on the light incident surface 15b side of the semiconductor substrate 15 of the imaging element 100 including the color filter 154 having the high refractive index.

### <10.3 Modification 2>

Next, a modification 2 of the present embodiment is described in detail with reference to FIGS. 19A and 19B. FIG. 19A is an illustrative diagram illustrating a planar configuration example of the color filter unit 74 according to the present modification, and FIG. 19B is an illustrative diagram illustrating a cross-sectional configuration example of the color filter unit 74 according to the present modification; this specifically is a cross-sectional view taken along line H-H′ in FIG. 19A. In the present modification, as illustrated in FIGS. 19A and 19B, in the configuration according to the modification 3 of the fifth embodiment, the roughness 170 is provided only on the surface on the light incident surface 15b side of the semiconductor substrate 15 of the imaging element 100 including the color filter 154 having the high refractive index.

### 11. Ninth Embodiment

### <11.1 Detailed Configuration>

Next, a ninth embodiment of the present disclosure is described in detail with reference to FIGS. 20A and 20B. FIG. 20A is an illustrative diagram illustrating a planar configuration example of the color filter unit 74 according to the present embodiment, and FIG. 20B is an illustrative diagram illustrating a cross-sectional configuration example of the color filter unit 74 according to the present embodiment; this specifically is a cross-sectional view taken along line J-J′ in FIG. 20A.

In the embodiments described so far, the refractive index of the color filter 154 is in two stages of the high refractive index and the low refractive index, but in the present disclosure, there is no limitation, and the refractive index of the color filter 154 may be in a plurality of stages. By doing so, by applying the color filters 154 having different refractive indexes to the imaging elements 100 of the same type, a sensitivity ratio may be created between the imaging elements 100, and the dynamic range of the imaging device 10 may be expanded.

Specifically, in the present embodiment, by adjusting the content of the photosensitive particles in the color filter 154, the refractive index of the color filter 154 may be set to three stages of Hn, Mn, and Ln (Hn>Mn>Ln), such as a high refractive index, a medium refractive index, and a low refractive index. Specifically, in the present embodiment, as illustrated in FIGS. 20A and 20B, the imaging element 100 including the color filter 154 having the high refractive index, the imaging element (third imaging element) 100 including the color filter 154 having the medium refractive index (represented as “Mn” in FIGS. 20A and 20B), and the imaging element 100 including the color filter 154 having the low refractive index are provided.

Note that, in the present embodiment, the refractive index of the color filter 154 is not limited to two stages or three stages, and may be of four or more stages, that is, a plurality of stages.

### <11.2 Modification 1>

Next, a modification 1 of the ninth embodiment of the present disclosure is described in detail with reference to FIG. 21. FIG. 21 is an illustrative diagram illustrating a cross-sectional configuration example of the color filter unit 74 according to the present modification, and specifically is a cross-sectional view taken along line J-J′ in FIG. 20A. That is, as illustrated in FIG. 21, in the present modification, a light incident surface 15b having roughness 170 is applied to the configuration according to the ninth embodiment.

### <11.3 Modification 2>

Next, a modification 2 of the ninth embodiment of the present disclosure is described in detail with reference to FIG. 22. FIG. 22 is an illustrative diagram illustrating a cross-sectional configuration example of the color filter unit 74 according to the present modification, and specifically is a cross-sectional view taken along line J-J′ in FIG. 20A. In the present modification, as illustrated in FIG. 22, in the configuration according to the ninth embodiment, the roughness 170 is provided only on the surface on the light incident surface 15b side of the semiconductor substrate 15 of the imaging element 100 including the color filter 154 having the high refractive index. Note that, in the present modification, the roughness 170 may be provided on the surface on the light incident surface 15b side of the semiconductor substrate 15 of the imaging element 100 including the color filter 154 having the medium refractive index.

### 12. Tenth Embodiment

Next, a tenth embodiment of the present disclosure is described in detail with reference to FIGS. 23 and 24. FIGS. 23 and 24 are illustrative diagrams illustrating a planar configuration example of a color filter unit 74 according to the present embodiment.

In the fifth embodiment described above, the color filter unit 74 includes a plurality of color filters 154 arrayed in two rows and two columns in a two-dimensional manner according to the Bayer array. However, in the present disclosure, the color filter unit 74 is not limited to including a plurality of color filters 154 arrayed in two rows and two columns in a two-dimensional manner according to the Bayer array.

Specifically, in the present embodiment, as illustrated in FIGS. 23 and 24, the color filter unit 74 includes a plurality of color filters 154 arrayed in four rows and four columns in a two-dimensional manner according to the Bayer array. In the present embodiment, the color filter 154 is, for example, a color filter that transmits light having a red wavelength component, a color filter that transmits light having a green wavelength component, and a color filter that transmits light having a blue wavelength component. Moreover, in the present embodiment also, the imaging elements 100 of the same type including the color filters 154 of the same type include the color filters 154 having different refractive indexes (in FIGS. 23 and 24, “Hn” is attached to the color filter 154 having the high refractive index, and “In” is attached to the color filter 154 having the low refractive index.).

More specifically, in a left diagram in FIG. 23, in the four imaging elements 100 of the same type arrayed in two rows and two columns including the color filters 154 of the same type, the two color filters 154 having the same refractive index are arranged on a diagonal line. In a right diagram in FIG. 23, the four color filters 154 that transmit light having the green wavelength component on an upper left part of the color filter unit 74 have a high refractive index, whereas the four color filters 154 that transmit light having the green wavelength component on a lower right part of the color filter unit 74 have a low refractive index.

In FIG. 24, in the four imaging elements 100 of the same type arrayed in two rows and two columns including the color filters 154 of the same type, the two color filters 154 having the same refractive index are arranged side by side in the horizontal direction or the vertical direction.

### 13. Eleventh Embodiment

Next, an eleventh embodiment of the present disclosure is described in detail with reference to FIGS. 25 to 27. FIGS. 25 to 27 are illustrative diagrams illustrating a planar configuration example of a color filter unit 74 according to the present embodiment.

In the present disclosure, the color filter 154 is not limited to, for example, a color filter that transmits light having a red wavelength component, a color filter that transmits light having a green wavelength component, and a color filter that transmits light having a blue wavelength component. The color filter 154 can be, for example, a color filter 154 that transmits white light as illustrated in FIG. 25, a color filter 154 that transmits yellow light, a color filter 154 that transmits magenta light, or a color filter 154 that transmits cyan light as illustrated in FIG. 26.

Note that, in the drawings attached to the present specification, the color filter 154 that transmits light having a white wavelength component is indicated by “W”, and the color filter 154 that transmits light having a yellow wavelength component is indicated by “Y”. The color filter 154 that transmits light having a cyan wavelength component is indicated by “C”, and the color filter 154 that transmits light having a magenta wavelength component is indicated by “M”.

In the present disclosure, the color filter unit 74 is not limited to including a plurality of color filters 154 arrayed in two rows and two columns or four rows and four columns; for example, as illustrated in a left diagram in FIG. 27, the color filter unit 74 may include a plurality of color filters 154 arrayed in six rows and six columns. Alternatively, in the present disclosure, as illustrated in a right diagram in FIG. 27, the color filter unit 74 may include a plurality of color filters 154 arrayed in eight rows and eight columns. That is, in the present embodiment, the array of a plurality of color filters 154 in the color filter unit 74 can be variously modified.

### <<14. Summary>>

As described above, according to the embodiment of the present disclosure, by making the refractive index of the color filter 154 of a specific imaging element 100 higher than that of the color filter 154 of the remaining imaging elements 100, light is easily guided to the imaging element 100 including the color filter 154 having the high refractive index, and light is guided to the imaging element 100 including the color filter 154 having the low refractive index with difficulty. Therefore, according to the present embodiment, the sensitivity of the specific imaging element 100 further increases, and the sensitivity of other imaging elements 100 further decreases. As a result, in the present embodiment, a sensitivity ratio occurs or increases between the imaging elements 100a, so that a dynamic range of the imaging device 10 can be expanded.

The imaging device 10 according to the embodiment of the present disclosure can be manufactured by using a method, an apparatus, and conditions used for manufacturing a general semiconductor device. That is, the imaging device 10 according to the present embodiment can be manufactured using an existing step of manufacturing the semiconductor device.

Examples of the above-described method include a physical vapor deposition (PVD) method, a chemical vapor deposition (CVD) method, and an atomic layer deposition (ALD) method. Examples of the PVD method include a vacuum vapor deposition method, an electron beam (EB) vapor deposition method, various sputtering methods (magnetron sputtering method, radio frequency (RF)-direct current (DC) coupled bias sputtering method, electron cyclotron resonance (ECR) sputtering method, counter target sputtering method, high-frequency sputtering method and the like), an ion plating method, a laser ablation method, a molecular beam epitaxy (MBE) method, and a laser transfer method. Examples of the CVD method include a plasma CVD method, a thermal CVD method, an organic metal (MO) CVD method, and a photo CVD method. Moreover, other methods include an electrolytic plating method, an electroless plating method, and a spin coating method; an immersion method; a cast method; a micro-contact printing; a drop cast method; various printing methods such as a screen printing method, an inkjet printing method, an offset printing method, a gravure printing method, and a flexographic printing method; a stamping method; a spray method; various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calender coater method. Moreover, examples of the patterning method include chemical etching such as shadow mask, laser transfer, and photolithography, and physical etching using ultraviolet rays, laser and the like. In addition, examples of a planarization technology include a chemical mechanical polishing (CMP) method, a laser planarization method, a reflow method and the like.

### 15. Application Example

### 15.1 Application Example to Camera

The technology according to the present disclosure (present technology) can be further applied to various products. For example, the technology according to the present disclosure may be applied to a camera and the like. Therefore, a configuration example of a camera 700 as an electronic device to which the present technology is applied is described with reference to FIG. 28. FIG. 28 is an explanatory diagram illustrating an example of a schematic functional configuration of the camera 700 to which the technology according to the present disclosure (the present technology) might be applied.

As illustrated in FIG. 28, the camera 700 includes an imaging device 10, an optical lens 710, a shutter mechanism 712, a drive circuit unit 714, and a signal processing circuit unit 716. The optical lens 710 forms an image of image light (incident light) from a subject on an imaging surface of the imaging device 10. As a result, signal charges are accumulated in an imaging element 100 of the imaging device 10 for a certain period of time. The shutter mechanism 712 opens and closes to control a light irradiation period and a light shielding period for the imaging device 10. The drive circuit unit 714 supplies a drive signal for controlling a signal transfer operation of the imaging device 10, a shutter operation of the shutter mechanism 712 and the like to them. That is, the imaging device 10 performs signal transfer on the basis of a drive signal (timing signal) supplied from the drive circuit unit 714. The signal processing circuit unit 716 performs various types of signal processing. For example, the signal processing circuit unit 716 outputs a video signal subjected to the signal processing to, for example, a storage medium (not illustrated) such as a memory, or to a display unit (not illustrated).

The configuration example of the camera 700 is described above. Each of the above-described components may be configured using a general-purpose member, or may be configured by hardware specialized for the function of each component. Such configuration can be appropriately changed according to the technical level at the time of implementation.

### 15.2 Application Example to Smartphone

For example, the technology according to the present disclosure may be applied to a smartphone and the like. Therefore, a configuration example of a smartphone 900 as an electronic device to which the present technology is applied is described with reference to FIG. 29. FIG. 29 is a block diagram illustrating an example of a schematic functional configuration of the smartphone 900 to which the technology according to the present disclosure (the present technology) might be applied.

As illustrated in FIG. 29, the smartphone 900 includes a central processing unit (CPU) 901, a read only memory (ROM) 902, and a random access memory (RAM) 903. The smartphone 900 includes a storage device 904, a communication module 905, and a sensor module 907. Moreover, the smartphone 900 includes an imaging device 10, a display device 910, a speaker 911, a microphone 912, an input device 913, and a bus 914. The smartphone 900 may include a processing circuit such as a digital signal processor (DSP) instead of or in addition to the CPU 901.

The CPU 901 functions as an arithmetic processing device and a control device, and controls an entire operation in the smartphone 900 or a part thereof according to various programs recorded in the ROM 902, the RAM 903, the storage device 904 or the like. The ROM 902 stores programs, arithmetic parameters and the like used by the CPU 901. The RAM 903 primarily stores programs used in execution of the CPU 901, parameters that appropriately change in the execution and the like. The CPU 901, the ROM 902, and the RAM 903 are connected to one another by a bus 914. The storage device 904 is a device for data storage configured as an example of a storage unit of the smartphone 900. The storage device 904 includes, for example, a magnetic storage device such as a hard disk drive (HDD), a semiconductor storage device, an optical storage device and the like. The storage device 904 stores programs and various data executed by the CPU 901, various data externally acquired and the like.

The communication module 905 is a communication interface including, for example, a communication device for connecting to a communication network 906. The communication module 905 can be, for example, a communication card for wired or wireless local area network (LAN), Bluetooth (registered trademark), wireless USB (WUSB) and the like. The communication module 905 may be a router for optical communication, a router for asymmetric digital subscriber line (ADSL), a modem for various types of communication or the like. The communication module 905 transmits and receives signals and the like to and from the Internet and other communication devices using a predetermined protocol such as Transmission Control Protocol (TCP)/Internet Protocol (IP), for example. The communication network 906 connected to the communication module 905 is a network connected in a wired or wireless manner, and is, for example, the Internet, a home LAN, infrared communication, satellite communication or the like.

The sensor module 907 includes, for example, various sensors such as a motion sensor (for example, an acceleration sensor, a gyro sensor, a geomagnetic sensor and the like), a biological information sensor (for example, a pulse sensor, a blood pressure sensor, a fingerprint sensor and the like), or a position sensor (for example, a global navigation satellite system (GNSS) receiver and the like).

The imaging device 10 is provided on a surface of the smartphone 900, and can image an object and the like located on a back side or a front side of the smartphone 900. Specifically, the technology according to the present disclosure (the present technology) can be applied to the imaging device 10. Moreover, the imaging device 10 can further include an optical system mechanism (not illustrated) including an imaging lens, a zoom lens, a focus lens and the like, and a drive system mechanism (not illustrated) that controls operations of the above-described optical system mechanism. The above-described imaging device 10 condenses incident light from an object as an optical image, and the above-described signal processing circuit photoelectrically converts the formed optical image in units of pixels, reads a signal of each pixel as an imaging signal, and performs image processing to acquire a captured image.

The display device 910 is provided on the surface of the smartphone 900, and can be, for example, a display device such as a liquid crystal display (LCD) or an organic electro luminescence (EL) display. The display device 910 can display an operation screen, a captured image acquired by the above-described imaging device 10 and the like.

The speaker 911 can output, for example, a call voice, a voice accompanying a video content displayed by the display device 910 described above and the like to the user.

The microphone 912 can collect, for example, a call voice of the user, a voice including a command to activate a function of the smartphone 900, and a voice in a surrounding environment of the smartphone 900.

The input device 913 is a device operated by the user, such as a button, a keyboard, a touch panel, or a mouse, for example. The input device 913 includes an input control circuit that generates an input signal on the basis of information input by the user and outputs the same to the CPU 901. By operating the input device 913, the user can input various data to the smartphone 900 and give an instruction of a processing operation.

The configuration example of the smartphone 900 is described above. Each of the above-described components may be configured using a general-purpose member, or may be configured by hardware specialized for the function of each component. Such configuration can be appropriately changed according to the technical level at the time of implementation.

### 15.3 Application Example to Moving Device Control System

For example, the technology according to the present disclosure may be applied to a moving device control system and the like. Therefore, an example of the moving device control system to which the technology proposed in the present disclosure can be applied is described with reference to FIG. 30. FIG. 30 is a block diagram illustrating a configuration example of a vehicle control system 11, which is an example of the moving device control system to which the present technology is applied.

The vehicle control system 11 is provided in a vehicle 1 and performs processing related to travel assistance and automatic driving of the vehicle 1.

The vehicle control system 11 includes a vehicle control electronic control unit (ECU) 21, a communication unit 22, a map information accumulation unit 23, a position information acquisition unit 24, an external recognition sensor 25, an in-vehicle sensor 26, a vehicle sensor 27, a storage unit 28, a travel assistance/automatic driving control unit 29, a driver monitoring system (DMS) 30, a human machine interface (HMI) 31, and a vehicle control unit 32.

The vehicle control ECU 21, the communication unit 22, the map information accumulation unit 23, the position information acquisition unit 24, the external recognition sensor 25, the in-vehicle sensor 26, the vehicle sensor 27, the storage unit 28, the travel assistance/automatic driving control unit 29, the driver monitoring system (DMS) 30, the human machine interface (HMI) 31, and the vehicle control unit 32 are communicably connected to each other via a communication network 41. The communication network 41 includes, for example, an in-vehicle communication network, a bus and the like conforming to a digital bidirectional communication standard such as a controller area network (CAN), a local interconnect network (LIN), a local area network (LAN), FlexRay (registered trademark), or Ethernet (registered trademark). The communication network 41 may be selectively used depending on a type of data to be transmitted. For example, the CAN may be applied to data related to vehicle control, and the Ethernet may be applied to large-capacity data. Note that, each unit of the vehicle control system 11 may be directly connected not via the communication network 41 but by using, for example, wireless communication that assumes communication at a relatively short distance, such as near field communication (NFC) or Bluetooth (registered trademark).

Note that, hereinafter, in a case where each unit of the vehicle control system 11 performs communication via the communication network 41, description of the communication network 41 is omitted. For example, in a case where the vehicle control ECU 21 and the communication unit 22 perform communication via the communication network 41, it is simply described that the vehicle control ECU 21 and the communication unit 22 perform communication.

The vehicle control ECU 21 includes, for example, various processors such as a central processing unit (CPU) and a micro processing unit (MPU). The vehicle control ECU 21 can control an entire vehicle control system 11 or some functions.

The communication unit 22 can communicate with various devices inside and outside the vehicle, other vehicles, servers, base stations and the like, and transmit and receive various data. At that time, the communication unit 22 may perform communication using a plurality of communication systems.

Here, communication with the outside of the vehicle that can be executed by the communication unit 22 is schematically described. The communication unit 22 can communicate with a server (hereinafter, referred to as an external server) and the like present on an external network via a base station or an access point by a wireless communication system such as the fifth generation mobile communication system (5G), long term evolution (LTE), or dedicated short range communications (DSRC). The external network with which the communication unit 22 performs communication is, for example, the Internet, a cloud network, a network unique to a company or the like. The communication system performed by the communication unit 22 with respect to the external network is not particularly limited as long as this is a wireless communication system capable of performing digital bidirectional communication at a communication speed equal to or higher than a predetermined speed and at a distance equal to or longer than a predetermined distance.

For example, the communication unit 22 can communicate with a terminal present in the vicinity of a host vehicle using a peer to peer (P2P) technology. Examples of the terminal present in the vicinity of the host vehicle include, for example, a terminal worn by a moving body moving at a relatively low speed such as a pedestrian or a bicycle, a terminal installed in a store or the like with a position fixed, or a machine type communication (MTC) terminal. Moreover, the communication unit 22 can also perform V2X communication. The V2X communication refers to, for example, communication between the host vehicle and another vehicle, such as vehicle to vehicle communication with another vehicle, vehicle to infrastructure communication with a roadside device and the like, vehicle to home communication, and vehicle to pedestrian communication with a terminal and the like possessed by a pedestrian.

For example, the communication unit 22 can receive a program for updating software for controlling the operation of the vehicle control system 11 from the outside (over the air). Moreover, the communication unit 22 can receive map information, traffic information, information around the vehicle 1 and the like from the outside. For example, the communication unit 22 can transmit information regarding the vehicle 1, information around the vehicle 1 and the like to the outside. Examples of the information regarding the vehicle 1 transmitted to the outside by the communication unit 22 include, for example, data indicating a state of the vehicle 1, a recognition result by the recognition unit 73 and the like. Moreover, for example, the communication unit 22 can also perform communication corresponding to a vehicle emergency call system such as an eCall.

For example, the communication unit 22 can receive an electromagnetic wave transmitted by a Vehicle Information and Communication System (VICS) (registered trademark) such as a radio wave beacon, an optical beacon, or FM multiplex broadcasting.

Communication with the inside of the vehicle that can be executed by the communication unit 22 is schematically described. The communication unit 22 can communicate with each device in the vehicle by using, for example, wireless communication. The communication unit 22 can perform wireless communication with a device in the vehicle by a communication system capable of performing digital bidirectional communication at a communication speed equal to or higher than a predetermined speed by wireless communication, such as wireless LAN, Bluetooth (registered trademark), NFC, or wireless USB (WUSB). There is no limitation, and the communication unit 22 can communicate with each device in the vehicle by using wired communication. For example, the communication unit 22 can communicate with each device in the vehicle by wired communication via a cable connected to a connection terminal not illustrated. The communication unit 22 can communicate with each device in the vehicle by a communication system capable of performing digital bidirectional communication at a predetermined communication speed or higher speed by wired communication, such as Universal Serial Bus (USB), High-Definition Multimedia Interface (HDMI) (registered trademark), or Mobile High-definition Link (MHL).

Here, the device in the vehicle refers to, for example, a device that is not connected to the communication network 41 in the vehicle. As the device in the vehicle, for example, a mobile device or a wearable device carried by a passenger such as a driver, an information device brought into the vehicle and temporarily installed and the like is assumed.

The map information accumulation unit 23 can accumulate one or both of a map acquired from the outside and a map created by the vehicle 1. For example, the map information accumulation unit 23 accumulates a three-dimensional high-precision map, a global map having lower precision than the high-precision map and covering a wide area and the like.

The high-precision map is, for example, a dynamic map, a point cloud map, a vector map and the like. The dynamic map is, for example, a map including four layers of dynamic information, semi-dynamic information, semi-static information, and static information, and is provided to the vehicle 1 from the external server and the like. The point cloud map is a map including a point cloud (point group data). The vector map is, for example, a map in which traffic information such as a lane and a position of a traffic light is associated with the point cloud map and adapted to an advanced driver assistance system (ADAS) or autonomous driving (AD).

The point cloud map and the vector map may be provided from, for example, the external server and the like, or may be created by the vehicle 1 as a map for performing matching with a local map to be described later on the basis of a sensing result by a camera 51, a radar 52, a LiDAR 53 and the like, and may be accumulated in the map information accumulation unit 23. In a case where the high-precision map is provided from the external server and the like, for example, map data of several hundred meters square regarding a planned path on which the vehicle 1 travels from now is acquired from the external server and the like in order to reduce a communication capacity.

The position information acquisition unit 24 can receive, from a global navigation satellite system (GNSS) satellite, a GNSS signal and acquire position information of the vehicle 1. The acquired position information is supplied to the travel assistance/automatic driving control unit 29. Note that, the position information acquisition unit 24 is not limited to the system using the GNSS signal, and may acquire the position information using, for example, a beacon.

The external recognition sensor 25 includes various sensors used for recognizing a situation outside the vehicle 1, and can supply sensor data from each sensor to each unit of the vehicle control system 11. The type and number of sensors included in the external recognition sensor 25 are not particularly limited.

For example, the external recognition sensor 25 includes the camera 51, the radar 52, the light detection and ranging or laser imaging detection and ranging (LiDAR) 53, and an ultrasonic sensor 54. There is no limitation, and the external recognition sensor 25 may have a configuration including one or more types of sensors out of the camera 51, the radar 52, the LiDAR 53, and the ultrasonic sensor 54. The numbers of the cameras 51, the radars 52, the LiDAR 53, and the ultrasonic sensors 54 are not particularly limited as long as they can be practically installed in the vehicle 1. The type of sensor included in the external recognition sensor 25 is not limited to this example, and the external recognition sensor 25 may include other types of sensors. An example of a sensing region of each sensor included in the external recognition sensor 25 is described later.

Note that, an imaging system of the camera 51 is not particularly limited. For example, cameras of various imaging systems such as a time of flight (ToF) camera, a stereo camera, a monocular camera, and an infrared camera, which are imaging systems capable of ranging, can be applied to the camera 51 as necessary. Moreover, the camera 51 may simply acquire a captured image regardless of ranging. The imaging device 10 according to the embodiment of the present disclosure can be applied to the camera 51.

For example, the external recognition sensor 25 can include an environment sensor for detecting an environment for the vehicle 1. The environment sensor is a sensor for detecting the environment such as weather, meteorological phenomena, and brightness, and can include various sensors such as a raindrop sensor, a fog sensor, a sunshine sensor, a snow sensor, and an illuminance sensor, for example.

Moreover, for example, the external recognition sensor 25 includes a microphone used for detecting a sound around the vehicle 1, a position of a sound source and the like.

The in-vehicle sensor 26 includes various sensors used for detecting information inside the vehicle, and can supply sensor data from each sensor to each unit of the vehicle control system 11. The type and number of various sensors included in the in-vehicle sensor 26 are not particularly limited as long as they are type and number that can be practically installed in the vehicle 1.

For example, the in-vehicle sensor 26 can include one or more types of sensors out of a camera, a radar, a seating sensor, a steering wheel sensor, a microphone, and a biological sensor. As the camera included in the in-vehicle sensor 26, for example, cameras of various imaging systems capable of ranging, such as a ToF camera, a stereo camera, a monocular camera, and an infrared camera can be used. There is no limitation, and the camera included in the in-vehicle sensor 26 may be a camera for simply acquiring a captured image regardless of ranging. The imaging device 10 according to the embodiment of the present disclosure can be applied to the camera included in the in-vehicle sensor 26. The biological sensor included in the in-vehicle sensor 26 is provided, for example, on a seat, a steering wheel and the like, and detects various types of biological information of the passenger such as the driver.

The vehicle sensor 27 includes various sensors used for detecting a state of the vehicle 1, and can supply sensor data from each sensor to each unit of the vehicle control system 11. The type and number of various sensors included in the vehicle sensor 27 are not particularly limited as long as they are type and number that can be practically installed in the vehicle 1.

For example, the vehicle sensor 27 can include a speed sensor, an acceleration sensor, an angular velocity sensor (gyro sensor), and an inertial measurement unit (IMU) integrating them. For example, the vehicle sensor 27 includes a steering angle sensor that detects a steering angle of a steering wheel, a yaw rate sensor, an accelerator sensor that detects an operation amount of an accelerator pedal, and a brake sensor that detects an operation amount of a brake pedal. For example, the vehicle sensor 27 includes a rotation sensor that detects a rotation speed of an engine or a motor, an air pressure sensor that detects an air pressure of a tire, a slip rate sensor that detects a slip rate of the tire, and a wheel speed sensor that detects a rotation speed of a wheel. For example, the vehicle sensor 27 includes a battery sensor that detects a remaining amount and temperature of the battery, and an impact sensor that detects an external impact.

The storage unit 28 includes at least one of a nonvolatile storage medium and a volatile storage medium, and can store data and a program. The storage unit 28 is used as, for example, an electrically erasable programmable read-only memory (EEPROM) and a random access memory (RAM), and a magnetic storage device such as a hard disc drive (HDD), a semiconductor storage device, an optical storage device, and a magneto-optical storage device can be applied as the storage medium. The storage unit 28 stores various programs and data used by each unit of the vehicle control system 11. For example, the storage unit 28 includes an event data recorder (EDR) and a data storage system for automated driving (DSSAD), and stores information of the vehicle 1 before and after an event such as an accident and information acquired by the in-vehicle sensor 26.

The travel assistance/automatic driving control unit 29 can control travel assistance and automatic driving of the vehicle 1. For example, the travel assistance/automatic driving control unit 29 includes an analysis unit 61, an action planning unit 62, and an operation control unit 63.

The analysis unit 61 can perform analysis processing of the situation of the vehicle 1 and around the same. The analysis unit 61 includes a self-position estimation unit 71, a sensor fusion unit 72, and a recognition unit 73.

The self-position estimation unit 71 can estimate a self-position of the vehicle 1 on the basis of the sensor data from the external recognition sensor 25 and the high-precision map accumulated in the map information accumulation unit 23. For example, the self-position estimation unit 71 generates a local map on the basis of the sensor data from the external recognition sensor 25, and estimates the self-position of the vehicle 1 by matching the local map with the high-precision map. The position of the vehicle 1 can be based on, for example, the center of a rear wheel pair axle.

The local map is, for example, a three-dimensional high-precision map created using a technology such as simultaneous localization and mapping (SLAM), an occupancy grid map and the like. The three-dimensional high-precision map is, for example, the above-described point cloud map and the like. The occupancy grid map is a map in which a three-dimensional or two-dimensional space around the vehicle 1 is divided into grids of a predetermined size, and an occupancy state of an object is indicated in units of grids. The occupancy state of the object is indicated by, for example, presence or absence or existence probability of the object. The local map is also used for detection processing and recognition processing of a situation outside the vehicle 1 by the recognition unit 73, for example.

Note that, the self-position estimation unit 71 may estimate the self-position of the vehicle 1 on the basis of the position information acquired by the position information acquisition unit 24 and the sensor data from the vehicle sensor 27.

The sensor fusion unit 72 can perform sensor fusion processing of combining a plurality of different types of sensor data (for example, image data supplied from the camera 51 and sensor data supplied from the radar 52) to obtain new information. Methods for combining different types of sensor data include integration, fusion, association and the like.

The recognition unit 73 can execute detection processing of detecting a situation outside the vehicle 1 and recognition processing of recognizing the situation outside the vehicle 1.

For example, the recognition unit 73 performs detection processing and recognition processing of a situation outside the vehicle 1 on the basis of information from the external recognition sensor 25, information from the self-position estimation unit 71, information from the sensor fusion unit 72 and the like.

Specifically, for example, the recognition unit 73 performs detection processing, recognition processing and the like of an object around the vehicle 1. The object detection processing is, for example, processing of detecting the presence or absence, size, shape, position, motion and the like of an object. The object recognition processing is, for example, processing of recognizing an attribute such as a type of an object or identifying a specific object. Note that, the detection processing and the recognition processing are not necessarily clearly divided, and may overlap.

For example, the recognition unit 73 detects the object around the vehicle 1 by performing clustering to classify the point cloud based on the sensor data by the radar 52, the LiDAR 53 or the like into point group masses. As a result, the presence or absence, size, shape, and position of the object around the vehicle 1 are detected.

For example, the recognition unit 73 detects the motion of the object around the vehicle 1 by performing tracking that follows the motion of the point cloud mass classified by clustering. As a result, the speed and a travel direction (motion vector) of the object around the vehicle 1 are detected.

For example, the recognition unit 73 detects or recognizes a vehicle, a person, a bicycle, an obstacle, a structure, a road, a traffic light, a traffic sign, a road sign and the like on the basis of the image data supplied from the camera 51. The recognition unit 73 may recognize the type of the object around the vehicle 1 by performing recognition processing such as semantic segmentation.

For example, the recognition unit 73 can perform recognition processing of traffic rules around the vehicle 1 on the basis of the map accumulated in the map information accumulation unit 23, an estimation result of the self-position by the self-position estimation unit 71, and a recognition result of an object around the vehicle 1 by the recognition unit 73. By this processing, the recognition unit 73 can recognize the position and the state of the traffic light, contents of the traffic sign and the road sign, contents of traffic regulation, a travelable lane and the like.

For example, the recognition unit 73 can perform recognition processing of the environment around the vehicle 1. As the surrounding environment to be recognized by the recognition unit 73, weather, temperature, humidity, brightness, a state of a road surface and the like are assumed.

The action planning unit 62 creates an action plan of the vehicle 1. For example, the action planning unit 62 can create the action plan by performing processing of global path planning and path following.

Note that, the global path planning is processing of planning a global path from the start to the goal. This global path planning also includes processing referred to as local path planning of performing local path planning that enables safe and smooth travel in the vicinity of the vehicle 1 in consideration of motion characteristics of the vehicle 1 in the planned path.

The path following is processing of planning an operation for safely and accurately traveling on the path planned by the global path planning within a planned time. For example, the action planning unit 62 can calculate the target speed and the target angular velocity of the vehicle 1 on the basis of a result of the processing of the path following.

The operation control unit 63 can control the operation of the vehicle 1 in order to implement the action plan created by the action planning unit 62.

For example, the operation control unit 63 controls a steering control unit 81, a brake control unit 82, and a drive control unit 83 included in the vehicle control unit 32 to be described later, and performs acceleration/deceleration control and direction control so that the vehicle 1 travels on the path calculated by the local path planning. For example, the operation control unit 63 performs cooperative control for the purpose of implementing the functions of the ADAS such as collision avoidance or impact alleviation, follow-up travel, vehicle speed maintaining travel, collision warning of the host vehicle, lane deviation warning of the host vehicle and the like. For example, the operation control unit 63 performs cooperative control for the purpose of automatic driving and the like in which the vehicle autonomously travels without depending on the operation of the driver.

The DMS 30 can perform driver authentication processing, driver state recognition processing and the like on the basis of sensor data from the in-vehicle sensor 26, input data input to the HMI 31 to be described later and the like. As the state of the driver to be recognized, for example, a physical condition, a wakefulness level, a concentration level, a fatigue level, a line-of-sight direction, a drunkenness level, a driving operation, a posture and the like are assumed.

Note that, the DMS 30 may perform authentication processing of a passenger other than the driver and recognition processing of a state of the passenger. For example, the DMS 30 may perform recognition processing of the situation inside the vehicle on the basis of the sensor data from the in-vehicle sensor 26. As the situation inside the vehicle to be recognized, for example, temperature, humidity, brightness, odor and the like are assumed.

The HMI 31 can input various data, instructions and the like and present various data to the driver and the like.

Data input by the HMI 31 is schematically described. The HMI 31 includes an input device for a person to input data. The HMI 31 generates an input signal on the basis of data, an instruction and the like input by the input device, and supplies the same to each unit of the vehicle control system 11. The HMI 31 includes operators such as a touch panel, a button, a switch, and a lever as input devices, for example. There is no limitation, and the HMI 31 may further include the input device capable of inputting information by a method other than a manual operation by voice, gesture and the like. Moreover, the HMI 31 may use, for example, a remote control device using infrared rays or radio waves, or an external connection device such as a mobile device or a wearable device corresponding to the operation of the vehicle control system 11 as the input device.

Data presentation by the HMI 31 is schematically described. The HMI 31 generates visual information, auditory information, and tactile information for the passenger or the outside of the vehicle. The HMI 31 performs output control for controlling output, output content, output timing, output method and the like of each piece of generated information. The HMI 31 generates and outputs, as the visual information, for example, information indicated by an image and light such as an operation screen, a state display of the vehicle 1, a warning display, and a monitor image indicating a situation around the vehicle 1. The HMI 31 generates and outputs, as the auditory information, for example, information indicated by sounds such as voice guidance, a warning sound, and a warning message. Moreover, the HMI 31 generates and outputs, as the tactile information, for example, information given to the tactile sense of the passenger by force, vibration, motion and the like.

As an output device with which the HMI 31 outputs the visual information, for example, a display device that presents the visual information by displaying an image by the device itself or a projector device that presents the visual information by projecting an image can be applied. Note that, the display device may be a device that displays the visual information in the field of view of the passenger, such as a head-up display, a transmissive display, or a wearable device having an augmented reality (AR) function, for example, in addition to a display device including a normal display. The HMI 31 can also use a display device included in a navigation device, an instrument panel, a camera monitoring system (CMS), an electronic mirror, a lamp and the like provided in the vehicle 1 as an output device that outputs the visual information.

As an output device with which the HMI 31 outputs the auditory information, for example, an audio speaker, a headphone, or an earphone can be applied.

As an output device with which the HMI 31 outputs the tactile information, for example, a haptic element using a haptic technology can be applied. The haptic element is provided, for example, in a portion with which the passenger of the vehicle 1 comes into contact, such as the steering wheel or seat.

The vehicle control unit 32 can control each unit of the vehicle 1. The vehicle control unit 32 includes the steering control unit 81, the brake control unit 82, the drive control unit 83, a body system control unit 84, a light control unit 85, and a horn control unit 86.

The steering control unit 81 can detect and control a state of a steering system of the vehicle 1. The steering system includes, for example, a steering mechanism including a steering wheel and the like, an electric power steering and the like. The steering control unit 81 includes, for example, a steering ECU that controls the steering system, an actuator that drives the steering system and the like.

The brake control unit 82 can detect and control a state of a brake system of the vehicle 1. The brake system includes, for example, a brake mechanism including a brake pedal and the like, an antilock brake system (ABS), a regenerative brake mechanism and the like. The brake control unit 82 includes, for example, a brake ECU that controls the brake system, an actuator that drives the brake system and the like.

The drive control unit 83 can detect and control a state of a drive system of the vehicle 1. The drive system includes, for example, a driving force generation device for generating a driving force such as an accelerator pedal, an internal combustion engine, or a driving motor, a driving force transmission mechanism for transmitting the driving force to wheels and the like. The drive control unit 83 includes, for example, a drive ECU that controls a drive system, an actuator that drives the drive system and the like.

The body system control unit 84 can detect and control a state of a body system of the vehicle 1. The body system includes, for example, a keyless entry system, a smart key system, a power window device, a power seat, an air conditioner, an airbag, a seat belt, a shift lever and the like. The body system control unit 84 includes, for example, a body system ECU that controls a body system, an actuator that drives the body system and the like.

The light control unit 85 can detect and control a state of various lights of the vehicle 1. As the light to be controlled, for example, a headlight, a backlight, a fog light, a turn signal, a brake light, a projection, a display of a bumper and the like are assumed. The light control unit 85 includes a light ECU that controls the light, an actuator that drives the light and the like.

The horn control unit 86 can detect and control a state of a car horn of the vehicle 1. The horn control unit 86 includes, for example, a horn ECU that controls the car horn, an actuator that drives the car horn and the like.

FIG. 31 is a diagram illustrating an example of sensing regions by the camera 51, the radar 52, the LiDAR 53, the ultrasonic sensor 54 and the like of the external recognition sensor 25 in FIG. 30. Note that, FIG. 31 schematically illustrates the vehicle 1 as viewed from above, in which a left end side is a front end (front) side of the vehicle 1 and a right end side is a rear end (rear) side of the vehicle 1.

A sensing region 101F and a sensing region 101B illustrate an example of the sensing regions of the ultrasonic sensor 54. The sensing region 101F covers a periphery of the front end of the vehicle 1 by a plurality of ultrasonic sensors 54. The sensing region 101B covers a periphery of the rear end of the vehicle 1 by a plurality of ultrasonic sensors 54.

Sensing results in the sensing region 101F and the sensing region 101B are used, for example, for parking assistance and the like of the vehicle 1.

Sensing regions 102F to 102B illustrate an example of the sensing regions of a short-distance or middle-distance radar 52. The sensing region 102F covers a position farther than the sensing region 101F in front of the vehicle 1. The sensing region 102B covers a position farther than the sensing region 101B behind the vehicle 1. The sensing region 102L covers a periphery of the rear of a left side surface of the vehicle 1. The sensing region 102R covers a periphery of the rear of a right side surface of the vehicle 1.

A sensing result in the sensing region 102F is used, for example, for detecting a vehicle, a pedestrian and the like present in front of the vehicle 1. A sensing result in the sensing region 102B is used, for example, for collision avoidance function behind the vehicle 1. Sensing results in the sensing region 102L and the sensing region 102R are used, for example, for detecting an object in a blind spot on the side of the vehicle 1.

Sensing regions 103F to 103B illustrate an example of the sensing regions by the camera 51. The sensing region 103F covers a position farther than the sensing region 102F in front of the vehicle 1. The sensing region 103B covers a position farther than the sensing region 102B behind the vehicle 1. The sensing region 103L covers a periphery of the left side surface of the vehicle 1. The sensing region 103R covers a periphery of the right side surface of the vehicle 1.

A sensing result in the sensing region 103F can be used for, for example, recognition of a traffic light or a traffic sign, a lane deviation avoidance assistance system, and an automatic headlight control system. A sensing result in the sensing region 103B can be used for, for example, parking assistance and a surround view system. Sensing results in the sensing region 103L and the sensing region 103R can be used, for example, for the surround view system.

A sensing region 104 illustrates an example of the sensing region of the LiDAR 53. The sensing region 104 covers a position farther than the sensing region 103F in front of the vehicle 1. In contrast, the sensing region 104 has a narrower range in a right-to-left direction than that of the sensing region 103F.

A sensing result in the sensing region 104 is used, for example, for detecting an object such as a peripheral vehicle.

A sensing region 105 illustrates an example of the sensing region of a long-distance radar 52. The sensing region 105 covers a position farther than the sensing region 104 in front of the vehicle 1. In contrast, the sensing region 105 has a narrower range in a right-to-left direction than that of the sensing region 104.

A sensing result in the sensing region 105 is used for, for example, adaptive cruise control (ACC), emergency braking, collision avoidance and the like.

Note that, the sensing regions of the sensors of the camera 51, the radar 52, the LiDAR 53, and the ultrasonic sensor 54 included in the external recognition sensor 25 may have various configurations other than those in FIG. 31. Specifically, the ultrasonic sensor 54 may also sense the side of the vehicle 1, or the LiDAR 53 may sense the rear of the vehicle 1. An installation position of each sensor is not limited to each example described above. The number of sensors may be one or more.

### <<16. Supplement>>

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive of various changes or modifications within the scope of the technical idea recited in claims, and it is naturally understood that these also belong to the technical scope of the present disclosure.

The effects described in the present specification are merely illustrative or exemplary, and are not restrictive. That is, the technology according to the present disclosure can exhibit other effects obvious to those skilled in the art from the description of the present specification together with or instead of the above effects.

Note that, the present technology can also have the following configurations.
(1) An imaging device comprising:
   a pixel array unit formed by arraying unit regions including a plurality of imaging elements including a first imaging element and a second imaging element in a two-dimensional array, wherein
   each of the first imaging element and the second imaging element includes
   a color filter that transmits light having a wavelength of a predetermined wavelength band, and
   the color filter included in the first imaging element has a higher refractive index than a refractive index of the color filter included in the second imaging element.
(2) The imaging device according to (1), wherein the color filter included in the first imaging element includes photosensitive particles.
(3) The imaging device according to (2), wherein the color filter included in the second imaging element does not include the photosensitive particles.
(4) The imaging device according to (2), wherein the color filter included in the second imaging element includes the photosensitive particles at a concentration lower than a concentration of the color filter included in the first imaging element.
(5) The imaging device according to any one of (2) to (4), wherein the photosensitive particles include at least one selected from a group including titanium oxide particles, zirconium oxide particles, zinc oxide particles, and nanodiamond particles.
(6) The imaging device according to any one of (1) to (5), wherein
in plan view,
the first and second imaging elements have a polygonal shape, and
an area of the first imaging element is larger than an area of the second imaging element.
(7) The imaging device according to any one of (1) to (6), wherein
   each of the first and second imaging elements includes:
   the color filter; and
   a photoelectric conversion unit that is provided in a semiconductor substrate located below the color filter and generates a charge by light incident on a light incident surface of the semiconductor substrate via the color filter, and
   the light incident surface located above the photoelectric conversion unit of the first imaging element has roughness.
(8) The imaging device according to (7), wherein the light incident surface located above the photoelectric conversion unit of the second imaging element is flat.
(9) The imaging device according to (7), wherein the light incident surface located above the photoelectric conversion unit of the second imaging element has roughness.
(10) The imaging device according to any one of (1) to (9), wherein
   the plurality of imaging elements includes a third imaging element including the color filter, and
   the color filter included in the third imaging element has a refractive index different from the refractive index of the color filter included in each of the first imaging element and the second imaging element.
(11) The imaging device according to (1), wherein the plurality of imaging elements includes four or more imaging elements each including the color filter, and the color filters included in the four or more imaging elements have refractive indexes different from one another.
(12) The imaging device according to any one of (1) to (11), wherein
   the color filter is
   a color filter that transmits red light, a color filter that transmits green light, or a color filter that transmits blue light.
(13) The imaging device according to any one of (1) to (11), wherein
   the color filter is
   a color filter that transmits red light, a color filter that transmits green light, a color filter that transmits blue light, or a color filter that transmits white light.
(14) The imaging device according to any one of (1) to (11), wherein
   the color filter is
   a color filter that transmits red light, a color filter that transmits green light, a color filter that transmits blue light, a color filter that transmits yellow light, a color filter that transmits magenta light, or a color filter that transmits cyan light.
(15) The imaging device according to any one of (1) to (6), wherein
   the plurality of imaging elements includes
   an imaging element that generates a charge by red light, an imaging element that generates a charge by green light, and an imaging element that generates a charge by blue light.
(16) The imaging device according to (15), wherein the plurality of imaging elements further includes an imaging element that generates a charge by white light.
(17) The imaging device according to (15) or (16), wherein
   the plurality of imaging elements further includes
   an imaging element that generates a charge by yellow light, an imaging element that generates a charge by magenta light, or an imaging element that generates a charge by cyan light.
(18) The imaging device according to any one of (1) to (17), wherein
   the unit region includes
   the plurality of imaging elements arrayed in two rows and two columns.
(19) The imaging device according to any one of (1) to (17), wherein
   the unit region includes
   the plurality of imaging elements arrayed in four rows and four columns.
(20) An electronic device equipped with an imaging device, wherein
   the imaging device includes
   a pixel array unit formed by arraying unit regions including a plurality of imaging elements including a first imaging element and a second imaging element in a two-dimensional array,
   each of the first imaging element and the second imaging element includes
   a color filter that transmits light having a wavelength of a predetermined wavelength band, and
   the color filter included in the first imaging element has a higher refractive index than a refractive index of the color filter included in the second imaging element.

### REFERENCE SIGNS LIST

10 IMAGING DEVICE
15 SEMICONDUCTOR SUBSTRATE
15a SURFACE
15b LIGHT INCIDENT SURFACE
33 PIXEL ARRAY UNIT
34 COLUMN SIGNAL PROCESSING CIRCUIT UNIT
35 VERTICAL DRIVE CIRCUIT UNIT
36 HORIZONTAL DRIVE CIRCUIT UNIT
38 OUTPUT CIRCUIT UNIT
40 CONTROL CIRCUIT UNIT
42 PIXEL DRIVE WIRING
44 VERTICAL SIGNAL LINE
46 HORIZONTAL SIGNAL LINE
48 INPUT/OUTPUT TERMINAL
74 COLOR FILTER UNIT
100 IMAGING ELEMENT
120 PHOTOELECTRIC CONVERSION UNIT
150 ON-CHIP LENS
154 COLOR FILTER
156 LIGHT SHIELDING UNIT
170 ROUGHNESS
180 INTERLAYER INSULATING FILM
700 CAMERA
710 OPTICAL LENS
712 SHUTTER MECHANISM
714 DRIVE CIRCUIT UNIT
716 SIGNAL PROCESSING CIRCUIT UNIT
900 SMARTPHONE
901 CPU
902 ROM
903 RAM
904 STORAGE DEVICE
905 COMMUNICATION MODULE
906 COMMUNICATION NETWORK
907 SENSOR MODULE
910 DISPLAY DEVICE
911 SPEAKER
912 MICROPHONE
913 INPUT DEVICE
914 BUS

1. An imaging device comprising:
a pixel array unit formed by arraying unit regions including a plurality of imaging elements including a first imaging element and a second imaging element in a two-dimensional array, wherein
each of the first imaging element and the second imaging element includes
a color filter that transmits light having a wavelength of a predetermined wavelength band, and
the color filter included in the first imaging element has a higher refractive index than a refractive index of the color filter included in the second imaging element.

2. The imaging device according to claim 1, wherein the color filter included in the first imaging element includes photosensitive particles.

3. The imaging device according to claim 2, wherein the color filter included in the second imaging element does not include the photosensitive particles.

4. The imaging device according to claim 2, wherein the color filter included in the second imaging element includes the photosensitive particles at a concentration lower than a concentration of the color filter included in the first imaging element.

5. The imaging device according to claim 2, wherein the photosensitive particles include at least one selected from a group including titanium oxide particles, zirconium oxide particles, zinc oxide particles, and nanodiamond particles.

6. The imaging device according to claim 1, wherein in plan view,
the first and second imaging elements have a polygonal shape, and
an area of the first imaging element is larger than an area of the second imaging element.

7. The imaging device according to claim 1, wherein
each of the first and second imaging elements includes:
the color filter; and
a photoelectric conversion unit that is provided in a semiconductor substrate located below the color filter and generates a charge by light incident on a light incident surface of the semiconductor substrate via the color filter, and
the light incident surface located above the photoelectric conversion unit of the first imaging element has roughness.

8. The imaging device according to claim 7, wherein the light incident surface located above the photoelectric conversion unit of the second imaging element is flat.

9. The imaging device according to claim 7, wherein the light incident surface located above the photoelectric conversion unit of the second imaging element has roughness.

10. The imaging device according to claim 1, wherein
the plurality of imaging elements includes a third imaging element including the color filter, and
the color filter included in the third imaging element has a refractive index different from the refractive index of the color filter included in each of the first imaging element and the second imaging element.

11. The imaging device according to claim 1, wherein the plurality of imaging elements includes four or more imaging elements each including the color filter, and the color filters included in the four or more imaging elements have refractive indexes different from one another.

12. The imaging device according to claim 1, wherein the color filter is
a color filter that transmits red light, a color filter that transmits green light, or a color filter that transmits blue light.

13. The imaging device according to claim 1, wherein the color filter is
a color filter that transmits red light, a color filter that transmits green light, a color filter that transmits blue light, or a color filter that transmits white light.

14. The imaging device according to claim 1, wherein the color filter is
a color filter that transmits red light, a color filter that transmits green light, a color filter that transmits blue light, a color filter that transmits yellow light, a color filter that transmits magenta light, or a color filter that transmits cyan light.

15. The imaging device according to claim 1, wherein the plurality of imaging elements includes
an imaging element that generates a charge by red light, an imaging element that generates a charge by green light, and an imaging element that generates a charge by blue light.

16. The imaging device according to claim 15, wherein the plurality of imaging elements further includes an imaging element that generates a charge by white light.

17. The imaging device according to claim 15, wherein the plurality of imaging elements further includes
an imaging element that generates a charge by yellow light, an imaging element that generates a charge by magenta light, or an imaging element that generates a charge by cyan light.

18. The imaging device according to claim 1, wherein the unit region includes
the plurality of imaging elements arrayed in two rows and two columns.

19. The imaging device according to claim 1, wherein the unit region includes
the plurality of imaging elements arrayed in four rows and four columns.

20. An electronic device equipped with an imaging device, wherein
the imaging device includes
a pixel array unit formed by arraying unit regions including a plurality of imaging elements including a first imaging element and a second imaging element in a two-dimensional array,
each of the first imaging element and the second imaging element includes
a color filter that transmits light having a wavelength of a predetermined wavelength band, and
the color filter included in the first imaging element has a higher refractive index than a refractive index of the color filter included in the second imaging element.
